(19) United States
(12) Patent Application Publication
(10) Pub. No.: US 2025/0300660 A1
(43) Pub. Date: Sep. 25, 2025

(54) ELECTROSTATIC DISCHARGE CIRCUIT AND ELECTROSTATIC DISCHARGE CONTROL SYSTEM

(71) Applicant: SK hynix Inc., Icheon-si (KR)

(72) Inventor: Seung Ho LEE, Icheon-si (KR)

(21) Appl. No.: 19/231,290

(22) Filed: Jun. 6, 2025

Related U.S. Application Data
(63) Continuation of application No. 18/471,094, filed on Sep. 20, 2023.
Application No. 18/471,094 is a division of application No. 17/713,158, filed on Apr. 4, 2022, now Pat. No. 11,799,482.
Application No. 17/713,158 is a continuation-in-part of application No. 17/362,655, filed on Jun. 29, 2021, now Pat. No. 12,327,828.
Application No. 17/362,655 is a continuation-in-part of application No. 17/076,474, filed on Oct. 21, 2020, now Pat. No. 11,296,694.
(60) Provisional application No. 63/181,013, filed on Apr. 28, 2021.

(30) Foreign Application Priority Data
Jun. 29, 2020 (KR) 10-2020-0079223
Jan. 28, 2021 (KR) 10-2021-0012351

(51) Int. Cl. H03K 19/0185; H02H 9/04

(52) U.S. Cl. CPC H03K 19/018521; H02H 9/046

(57) ABSTRACT

An electrostatic discharge circuit may include a control voltage generation circuit, an electrostatic detection circuit, a driving control circuit and a discharge driving circuit. The control voltage generation circuit may generate first to third control voltages through a division operation on a supply voltage. The electrostatic detection circuit may set a first setup voltage based on the first control voltage, and detect static electricity transferred through the first setup voltage. The driving control circuit may set a second setup voltage based on the second control voltage, and generate a driving control signal. The discharge driving circuit may set a third setup voltage based on the third control voltage, and perform a discharge operation on static electricity.

### CROSS-REFERENCE TO RELATED APPLICATIONS

The present application is a continuation application of U.S. patent application Ser. No. 18/471,094 filed on Sep. 20, 2023, which is a divisional application of U.S. patent application Ser. No. 17/713,158 filed on Apr. 4, 2022, which is a continuation-in-part application of U.S. patent application Ser. No. 17/076,474 filed on Oct. 21, 2020, which claims priority under 35 U.S.C. § 119 (a) to Korean patent application No. 10-2020-0079223 filed on Jun. 29, 2020, in the Korean Intellectual Property Office, U.S. patent application Ser. No. 17/362,655 filed on Jun. 29, 2021, which claims priority under 35 U.S.C. § 119 (a) to Korean patent application No. 10-2021-0012351 filed on Jan. 28, 2021, in the Korean Intellectual Property Office, and U.S. Provisional patent application No. 63/181,013 filed on Apr. 28, 2021, which are incorporated herein by reference in their entirety. The present Application includes the subject matter disclosed in U.S. patent application Ser. No. 17/362,655, which was incorporated by reference in U.S. patent application Ser. No. 17/713,158 and U.S. patent application Ser. No. 18/471,094, and is likewise incorporated herein by reference in its entirety. The present Application relies on this incorporation by reference to provide written description and enablement support for certain claimed subject matter.

### BACKGROUND

### 1. Technical Field

Various embodiments generally relate to an electrostatic discharge circuit and an electrostatic discharge control system, and more particularly, to an electrostatic discharge circuit and an electrostatic discharge control system, which can protect internal circuits of an integrated circuit from static electricity contained in power.

### 2. Related Art

In general, an integrated circuit including a semiconductor apparatus receives power, and performs various circuit operations. In order to stably perform the various circuit operations, the integrated circuit needs to receive stable power. However, the power applied to the integrated circuit may contain undesired static electricity having a high voltage.

Recently, with the development of technology, internal circuits mounted on the integrated circuit have been gradually reduced in size and highly integrated. In such a situation, a high voltage of static electricity included in power accompanies potentially destructive effects on the internal circuits. In particular, the high voltage of the static electricity may destruct a gate dielectric layer of a metal oxide semiconductor (MOS) transistor included in an internal circuit. Therefore, the integrated circuit includes an ESD (Electro-Static Discharge) circuit for protecting the internal circuits from the high voltage of the static electricity.

### SUMMARY

In an embodiment, an electrostatic discharge circuit may include: a control voltage generation circuit configured to generate a first control voltage, a second control voltage, and a third control voltage by dividing a supply voltage; an electrostatic detection circuit configured to set a first setup voltage based on the first control voltage, and generate an electrostatic detection signal by detecting static electricity contained in the first setup voltage; a driving control circuit configured to set a second setup voltage based on the second control voltage, and generate a driving control signal based on the electrostatic detection signal; and a discharge driving circuit configured to set a third setup voltage based on the third control voltage, and perform a discharge operation on static electricity contained in the third setup voltage based on the driving control signal.

In an embodiment, an electrostatic discharge control system may include: a first electrostatic discharge circuit configured to perform a discharge operation on static electricity contained in a first supply voltage; a second electrostatic discharge circuit configured to perform a discharge operation on static electricity contained in a second supply voltage, the first supply voltage having a higher voltage level than the second supply voltage; and a selection control circuit configured to selectively control the first or second electrostatic discharge circuit based on a selected supply voltage of the first and second supply voltages, the selected supply voltage being applied to a supply voltage terminal.

In an embodiment, an electrostatic discharge control system may include: a control signal generation circuit configured to generate a selection control signal based on a selected supply voltage of a first supply voltage and a second supply voltage, the selected supply voltage being applied to a supply voltage terminal; a control voltage generation circuit activated in response to the selection control signal when the selected supply voltage is the first supply voltage and configured to generate a first control voltage, a second control voltage, and a third control voltage by dividing the selected supply voltage; a first setup circuit configured to receive the selected supply voltage and generate a first setup voltage based on one of the first control voltage and the selection control signal; a detection circuit configured to detect static electricity contained in the first setup voltage and output an electrostatic detection signal; a second setup circuit configured to receive the selected supply voltage and generate a second setup voltage based on one of the second control voltage and the selection control signal; a driving circuit configured to generate a driving control signal based on the electrostatic detection signal; a third setup circuit configured to receive the selected supply voltage and generate a third setup voltage based on one of the third control voltage and the selection control signal; and a discharge circuit configured to form a discharge path for the third setup voltage based on the driving control signal.

In an embodiment, an electrostatic discharge circuit may include: a bias generation circuit configured to generate a bias voltage; an electrostatic sensing circuit configured to sense static electricity contained in a supply voltage and generate a driving control signal; and a discharge driving circuit configured to set a setup voltage based on the bias voltage, and perform a discharge operation on static electricity contained in the setup voltage based on the driving control signal.

### BRIEF DESCRIPTION OF THE DRAWINGS

FIG. 1 is a block diagram illustrating an electrostatic discharge circuit in accordance with an embodiment.

FIG. 2 is a circuit diagram illustrating the electrostatic discharge circuit of FIG. 1.

FIG. 3 illustrates an electrostatic discharge control system in accordance with an embodiment.

FIG. 4 illustrates a selection control circuit of FIG. 3.

FIG. 5 illustrates a second electrostatic discharge circuit of FIG. 3.

FIG. 6 illustrates a control voltage generation circuit in accordance with another embodiment.

FIG. 7 illustrates an electrostatic discharge control system in accordance with another embodiment.

FIG. 8 illustrates a control signal generation circuit of FIG. 7.

FIG. 9 is a block diagram illustrating an electrostatic discharge circuit in accordance with another embodiment.

FIG. 10 is a view illustrating an operation condition of a low voltage transistor in accordance with embodiments;

FIG. 11 is a circuit diagram illustrating an output driving circuit according to an embodiment of the present disclosure;

FIG. 12A is a circuit diagram illustrating a P-driver calibration circuit according to an embodiment of the present disclosure;

FIG. 12B is a circuit diagram illustrating an N-driver calibration circuit according to an embodiment of the present disclosure;

FIG. 13A is a block diagram illustrating a semiconductor output circuit device in accordance with example embodiments;

FIG. 13B is a block diagram illustrating the interface circuit block in FIG. 13A;

FIG. 14 is a diagram illustrating a configuration of a level shifter shown in FIG. 13B according to an embodiment of the present disclosure;

FIG. 15 is a block diagram illustrating an interface circuit block according to still another embodiment of the present disclosure;

FIG. 16 is a block diagram illustrating a driver bias controller according to an embodiment of the present disclosure;

FIG. 17 is a diagram illustrating signal inverter of FIG. 16 according to an embodiment of the present disclosure;

FIG. 18 is a diagram illustrating a first pad-state detector of FIG. 16 according to an embodiment of the present disclosure;

FIG. 19 is a diagram illustrating a P-driver bias control circuit of FIG. 16 according to an embodiment of the present disclosure;

FIG. 20 is a diagram illustrating a second pad-state detector of FIG. 16 according to an embodiment of the present disclosure; and

FIG. 21 is a diagram illustrating an N-driver bias control circuit of FIG. 16 according to an embodiment of the present disclosure.

### DETAILED DESCRIPTION

The description of the present disclosure is merely an embodiment for a structural and/or functional description. The scope of rights of the present disclosure should not be construed as being limited to embodiments described in the specification. That is, the scope of rights of the present disclosure should be understood as including equivalents, which may realize the technical spirit, because an embodiment may be modified in various ways and may have various forms. Furthermore, objects or effects proposed in the present disclosure do not mean that a specific embodiment should include all objects or effects or include only such effects. Accordingly, the scope of rights of the present disclosure should not be understood as being limited thereby.

The meaning of the terms that are described in this application should be understood as follows.

The terms, such as the “first” and the “second,” are used to distinguish one element from another element, and the scope of the present disclosure should not be limited by the terms. For example, a first element may be named a second element. Likewise, the second element may be named the first element.

An expression of the singular number should be understood as including plural expressions, unless clearly expressed otherwise in the context. The terms, such as “include” or “have,” should be understood as indicating the existence of a set characteristic, number, step, operation, element, part, or a combination thereof, not excluding a possibility of the existence or addition of one or more other characteristics, numbers, steps, operations, elements, parts, or a combination thereof.

In each of the steps, symbols (e.g., a, b, and c) are used for convenience of description, and the symbols do not describe an order of the steps. The steps may be performed in an order different from the order described in the context unless a specific order is clearly described in the context. That is, the steps may be performed according to a described order, may be performed substantially at the same time as the described order, or may be performed in reverse order of the described order.

All the terms used herein, including technological or scientific terms, have the same meanings as those that are typically understood by those skilled in the art, unless otherwise defined. Terms defined in commonly used dictionaries should be construed as with the same meanings as those in the context in related technology and should not be construed as with ideal or excessively formal meanings, unless clearly defined in the application.

Various embodiments are directed to an electrostatic discharge circuit which includes low voltage transistors and can protect an internal circuit of an integrated circuit from static electricity contained in a supply voltage.

Also, various embodiments are directed to an electrostatic discharge control system which can protect an internal circuit of an integrated circuit from static electricity contained in multiple supply voltages.

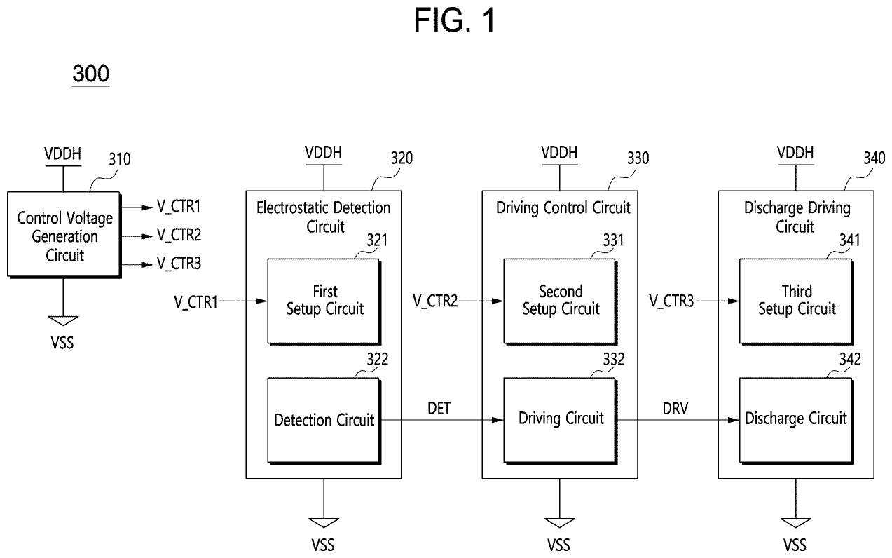

FIG. 1 is a block diagram illustrating an electrostatic discharge circuit 300 in accordance with an embodiment.

Referring to FIG. 1, the electrostatic discharge circuit 300 may be configured to sense and discharge static electricity contained in a supply voltage VDDH. More specifically, the electrostatic discharge circuit 300 may include a control voltage generation circuit 310, an electrostatic detection circuit 320, a driving control circuit 330, and a discharge driving circuit 340.

The control voltage generation circuit 310 may be configured to generate first to third control voltages V_CTR1 to V_CTR3 by dividing the supply voltage VDDH. The supply voltage VDDH may have a relatively high voltage level. For example, the supply voltage VDDH may be higher than an allowable voltage of a low voltage transistor included in the electrostatic discharge circuit 300. For example, the supply voltage VDDH may be one of approximately 3.3V+10%, approximately 2.5V+10%, and approximately 1.8V+10%. For reference, a supply voltage having a relatively low voltage level, which will be described below, may include the allowable voltage of the low voltage transistor. For example, the supply voltage having a relatively low voltage level may be one of approximately 1.8V+10%, approximately 1.2V+10%, and approximately 0.8V+10%. The control voltage generation circuit 310 may be coupled between a supply voltage terminal to which the supply voltage VDDH is applied and a ground voltage terminal to which a ground voltage VSS is applied.

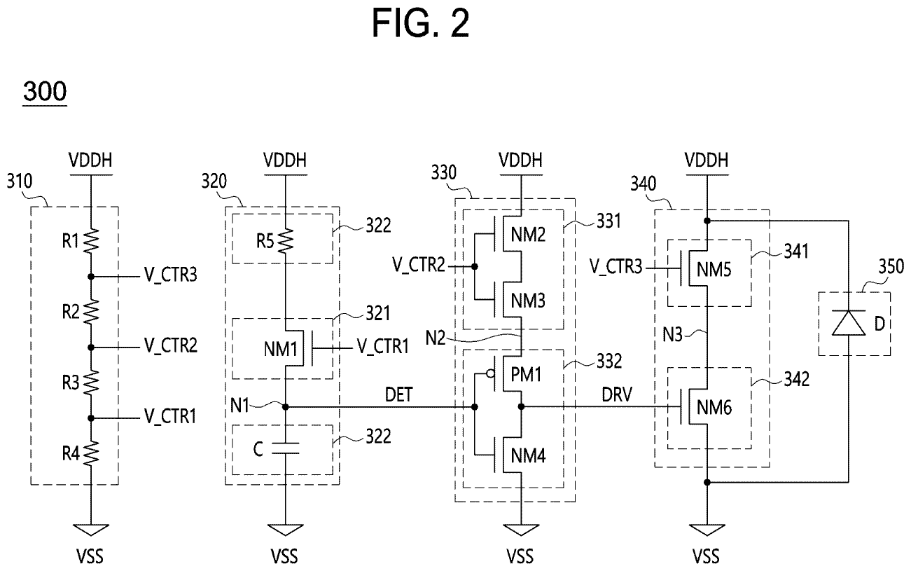

The first to third control voltages V_CTR1 to V_CTR3 generated by the control voltage generation circuit 310 may have the same voltage level. Furthermore, at least one of the first to third control voltages V_CTR1 to V_CTR3 may have a different voltage level from the other ones of the first to third control voltages V_CTR1 to V_CTR3. FIG. 2 illustrates the first to third control voltages V_CTR1 to V_CTR3 that have different voltage levels from one another.

The electrostatic detection circuit 320 may be configured to set a first setup voltage based on the first control voltage V_CTR1, and detect static electricity contained in the first setup voltage. The electrostatic detection circuit 320 may generate an electrostatic detection signal DET by detecting the static electricity. The electrostatic detection circuit 320 may be coupled between the supply voltage terminal and the ground voltage terminal. More specifically, the electrostatic detection circuit 320 may include a first setup circuit 321 and a detection circuit 322.

The first setup circuit 321 may be configured to receive the supply voltage VDDH, and generate the first setup voltage based on the first control voltage V_CTR1. The detection circuit 322 may be configured to detect the static electricity contained in the first setup voltage, and output the electrostatic detection signal DET. The detailed circuit configurations of the first setup circuit 321 and the detection circuit 322 will be described below with reference to FIG. 2.

The driving control circuit 330 may be configured to set a second setup voltage based on the second control voltage V_CTR2, and generate a driving control signal DRV based on the electrostatic detection signal DET. The driving control circuit 330 may be coupled between the supply voltage terminal and the ground voltage terminal. More specifically, the driving control circuit 330 may include a second setup circuit 331 and a driving circuit 332.

The second setup circuit 331 may be configured to receive the supply voltage VDDH, and generate the second setup voltage based on the second control voltage V_CTR2. The driving circuit 332 may be configured to generate the driving control signal DRV based on the electrostatic detection signal DET. The detailed circuit configurations of the second setup circuit 331 and the driving circuit 332 will be described below with reference to FIG. 2.

The discharge driving circuit 340 may be configured to set a third setup voltage based on the third control voltage V_CTR3, and perform a discharge operation on static electricity contained in the third setup voltage based on the driving control signal DRV. The discharge driving circuit 340 may be coupled between the supply voltage terminal and the ground voltage terminal. More specifically, the discharge driving circuit 340 may include a third setup circuit 341 and a discharge circuit 342.

The third setup circuit 341 may be configured to receive the supply voltage VDDH, and generate the third setup voltage based on the third control voltage V_CTR3. The discharge circuit 342 may be configured to form a discharge path for the third setup voltage based on the driving control signal DRV. The detailed circuit configurations of the third setup circuit 341 and the discharge circuit 342 will be described below with reference to FIG. 2.

FIG. 2 is a circuit diagram illustrating the electrostatic discharge circuit 300 of FIG. 1.

Referring to FIG. 2, the electrostatic discharge circuit 300 may include the control voltage generation circuit 310, the electrostatic detection circuit 320, the driving control circuit 330, and the discharge driving circuit 340.

The control voltage generation circuit 310 may include first to fourth resistors R1 to R4 coupled in series between the supply voltage terminal and the ground voltage terminal.

The first to fourth resistors R1 to R4 may generate the first to third control voltages V_CTR1 to V_CTR3 by dividing the supply voltage VDDH. The third control voltage V_CTR3 may be outputted from a node to which the first and second resistors R1 and R2 are coupled in common, the second control voltage V_CTR2 may be outputted from a node to which the second and third resistors R2 and R3 are coupled in common, and the first control voltage V_CTR1 may be outputted from a node to which the third and fourth resistors R3 and R4 are coupled in common. Therefore, the first to third control voltages V_CTR1 to V_CTR3 may have different voltage levels. Furthermore, the first to third control voltages V_CTR1 to V_CTR3 may have voltage levels which are sequentially reduced from a voltage level of the supply voltage VDDH. That is, among the first to third control voltages V_CTR1 to V_CTR3, the third control voltage V_CTR3 may have the highest voltage level, the second control voltage V_CTR2 may have the second highest voltage level, and the first control voltage V_CTR1 may have the lowest voltage level.

The control voltage generation circuit 310 having the above-described configuration may generate the first to third control voltages V_CTR1 to V_CTR3 by dividing the supply voltage VDDH.

According to another embodiment, the control voltage generation circuit 310 may include first to third resistors R1 to R3 coupled in series between the supply voltage terminal and the ground voltage terminal. The first to third resistors R1 to R3 may generate the first to third control voltages V_CTR1 to V_CTR3 by dividing the supply voltage VDDH. In an embodiment, the first and second control voltages V_CTR1 and V_CTR2 may have the same voltage level. In another embodiment, the second and third control voltages V_CTR2 and V_CTR3 may have the same voltage level.

The electrostatic detection circuit 320 may include the detection circuit 322 and the first setup circuit 321. The electrostatic detection circuit 320 may include a fifth resistor R5, a first NMOS transistor NM1, and a capacitor C, which are coupled in series between the supply voltage terminal and the ground voltage terminal. The first NMOS transistor NM1 may be included in the first setup circuit 321. The fifth resistor R5 and the capacitor C may be included in the detection circuit 322.

The first NMOS transistor NM1 may be coupled between the fifth resistor R5 and a first node N1, and configured to receive the first control voltage V_CTR1 through a gate terminal thereof. The first NMOS transistor NM1 may be turned on in response to the first control voltage V_CTR1. Thus, the supply voltage VDDH may be transferred to the first node N1 as the first setup voltage through the fifth resistor R5 and the first NMOS transistor NM1 when the first NMOS transistor NM1 is turned on. Therefore, the first node N1 may receive the first setup voltage.

The capacitor C may be coupled between the first node N1 and the ground voltage terminal. The capacitor C may be opened or shorted according to a current characteristic of the first setup voltage transferred to the first node N1. In other words, the capacitor C may be opened when the first setup voltage of the first node N1 has a DC characteristic, and shorted when the first setup voltage of the first node N1 has an AC characteristic. That is, the capacitor C may be opened or shorted according to the characteristic of a current flowing through the first node N1.

More specifically, when no static electricity is contained in the supply voltage VDDH, the first setup voltage of the first node N1 may have the DC characteristic. At this time, the capacitor C may be opened. Therefore, the first node N1 may have a voltage level corresponding to the supply voltage VDDH or a similar voltage level to the supply voltage VDDH. On the other hand, when static electricity is contained in the supply voltage VDDH, the voltage level of the supply voltage VDDH is instantaneously changed by a high voltage of the static electricity. Thus, the first setup voltage of the first node N1 may have the AC characteristic. At this time, the capacitor C may be shorted. Therefore, the first node N1 may have a voltage level corresponding to the ground voltage VSS or a similar voltage level to the ground voltage VSS.

That is, the first node N1 may have a voltage level changing according to whether static electricity is contained in the supply voltage VDDH or not. The changing voltage level at the first node N1 is output as the electrostatic detection signal DET, and thus the electrostatic detection signal DET indicates whether static electricity is contained in the supply voltage VDDH or not.

The electrostatic detection circuit 320 having the above-described configuration may provide the first setup voltage to the first node N1 in response to the first control voltage V_CTR1. The electrostatic detection circuit 320 may generate the electrostatic detection signal DET by detecting static electricity contained in the first setup voltage on the first node N1.

The driving control circuit 330 may include the second setup circuit 331 and the driving circuit 332. The driving control circuit 330 may include a second NMOS transistor NM2, a third NMOS transistor NM3, a first PMOS transistor PM1 and a fourth NMOS transistor NM4, which are coupled in series between the supply voltage terminal and the ground voltage terminal. The second and third NMOS transistors NM2 and NM3 may be included in the second setup circuit 331. The first PMOS transistor PM1 and the fourth NMOS transistor NM4 may be included in the driving circuit 332.

The second and third NMOS transistors NM2 and NM3 may be coupled in series between a second node N2 and the supply voltage terminal to, and receive the second control voltage V_CTR2 through gate terminals thereof. The second and third NMOS transistors NM2 and NM3 may be turned on in response to the second control voltage V_CTR2. Thus, the supply voltage VDDH may be transferred to the second node N2 as the second setup voltage through the second and third NMOS transistors NM2 and NM3. Therefore, the second node N2 may receive the second setup voltage.

The first PMOS transistor PM1 and the fourth NMOS transistor NM4 may be coupled in series between the second node N2 and the ground voltage terminal, and receive the electrostatic detection signal DET through gate terminals thereof. Thus, when the electrostatic detection signal DET has a voltage level corresponding to a logic high level, the fourth NMOS transistor NM4 may be turned on. On the other hand, when the electrostatic detection signal DET has a voltage level corresponding to a logic low level, the first PMOS transistor PM1 may be turned on.

As described above, the electrostatic detection signal DET may have a voltage level corresponding to the supply voltage VDDH when no static electricity is detected. That is, the electrostatic detection signal DET may have the logic high level when no static electricity is detected. Therefore, the fourth NMOS transistor NM4 may be turned on in response to the electrostatic detection signal DET having the logic high level. At this time, the driving control signal DRV may have a logic low level corresponding to the ground voltage VSS.

On the other hand, the electrostatic detection signal DET may have a voltage level corresponding to the ground voltage VSS when static electricity is detected. That is, the electrostatic detection signal DET may have the logic low level. Therefore, the first PMOS transistor PM1 may be turned on in response to the electrostatic detection signal DET having the logic low level. At this time, the driving control signal DRV may have a logic high level corresponding to the second setup voltage.

The driving control circuit 330 having the above-described configuration may provide the second setup voltage to the second node N2 in response to the second control voltage V_CTR2. Furthermore, the driving control circuit 330 may generate the driving control signal DRV based on the electrostatic detection signal DET.

The discharge driving circuit 340 may include the third setup circuit 341 and the discharge circuit 342. The discharge driving circuit 340 may include fifth and sixth NMOS transistors NM5 and NM6 coupled in series between the supply voltage terminal and the ground voltage terminal. The fifth NMOS transistor NM5 may be included in the third setup circuit 341. The sixth NMOS transistor NM6 may be included in the discharge circuit 342.

The fifth NMOS transistor NM5 may be coupled between a third node N3 and the supply voltage terminal, and receive the third control voltage V_CTR3 through a gate terminal thereof. The fifth NMOS transistor NM5 may be turned on in response to the third control voltage V_CTR3. The supply voltage VDDH may be transferred to the third node N3 as the third setup voltage through the fifth NMOS transistor NM5. Therefore, the third node N3 may receive the third setup voltage.

The sixth NMOS transistor NM6 may be coupled between the third node N3 and the ground voltage terminal, and receive the driving control signal DRV through a gate terminal thereof. When the driving control signal DRV has the logic low level, the sixth NMOS transistor NM6 may be turned off. On the other hand, when the driving control signal DRV has the logic high level, the sixth NMOS transistor NM6 may be turned on. Therefore, when the sixth NMOS transistor NM6 is turned on, the third node N3 and the ground voltage terminal may be coupled to each other. That is, the sixth NMOS transistor NM6 may form a discharge path for the third setup voltage on the third node N3 in response to the driving control signal DRV.

As described above, when no static electricity is detected, the driving control signal DRV may have the logic low level. The sixth NMOS transistor NM6 may be turned off in response to the driving control signal DRV having the logic low level. On the other hand, when static electricity is detected, the driving control signal DRV may have the logic high level. The sixth NMOS transistor NM6 may be turned on in response to the driving control signal DRV having the logic high level. At this time, the sixth NMOS transistor NM6 may form the discharge path. Therefore, the static electricity contained in the supply voltage VDDH may be discharged to the ground voltage terminal through the discharge path.

The discharge driving circuit 340 having the above-described configuration may provide the third setup voltage to the third node N3 in response to the third control voltage V_CTR3. Furthermore, the discharge driving circuit 340 may perform a discharge operation on the static electricity contained in the supply voltage VDDH based on the driving control signal DRV.

The electrostatic discharge circuit 300 in accordance with the present embodiment may use the supply voltage VDDH corresponding to a high voltage, e.g., 3.3V. The first to sixth NMOS transistors NM1 to NM6 and the first PMOS transistor PM1, which are included in the electrostatic discharge circuit 300, may be all implemented with low voltage transistors. The low voltage transistor may be a transistor which is used when implementing an integrated circuit using a low supply voltage, e.g., 1.8V.

In general, the low voltage transistor may occupy a smaller area and require a lower design cost than a high voltage transistor. As described above, the electrostatic discharge circuit 300 may detect and discharge the static electricity contained in the supply voltage VDDH corresponding to a high voltage, while using the low voltage transistors. In other words, the electrostatic discharge circuit 300 in accordance with the present embodiment may not only perform the discharge operation on the static electricity contained in the supply voltage VDDH, but also reduce an area occupied by the electrostatic discharge circuit 300.

The reason why the low voltage transistors are used in the electrostatic discharge circuit 300 in accordance with the present embodiment may be described as follows.

In general, a transistor may have a reliability guarantee condition depending on an operation characteristic thereof. The low voltage transistor may perform a normal circuit operation only when voltage levels of source, drain, and gate terminals of the transistor satisfy the reliability guarantee condition. In an integrated circuit using a low supply voltage, e.g., 1.8V, a voltage difference Vgd between the gate and drain terminals of the low voltage transistor, a voltage difference Vgs between the gate and source terminals thereof, and a voltage difference Vds between the drain and source terminals thereof need to have 1.98V or less to satisfy the reliability guarantee condition. The electrostatic discharge circuit 300 in accordance with the present embodiment may receive the supply voltage VDDH of 3.3V corresponding to a high voltage, and the first to sixth NMOS transistors NM1 to NM6 and the first PMOS transistor PM1 may each maintain the reliability guarantee condition for the low voltage transistor.

Hereafter, for convenience of description, it is assumed that the first control voltage V_CTR1, the second control voltage V_CTR2, and the third control voltage V_CTR3, which are obtained by dividing the supply voltage VDDH of 3.3V, have 2.3V, 2.4V, and 2.5V, respectively. Furthermore, it is assumed that threshold voltages of the first to sixth NMOS transistors NM1 to NM6 and the first PMOS transistor PM1 have 0.5V.

The first NMOS transistor NM1 may receive the first control voltage V_CTR1 of 2.3V through the gate terminal thereof. Therefore, a voltage difference Vgd between the gate and drain terminals may become 1V (=3.3V-2.3V), a voltage difference Vgs between the gate and source terminals may become 0.5V (=2.3V-1.8V), and a voltage difference Vds between the drain and source terminals may become 1.5V (=3.3V-1.8V), under the supposition that the fifth resistor R5 is ignored. That is, the above voltage differences among the gate, drain, and source terminals of the first NMOS transistor NM1 may have voltage levels in a range of 1.98V or less, which corresponds to the reliability guarantee condition for the low voltage transistor.

The second NMOS transistor NM2 may receive the second control voltage V_CTR2 of 2.4V through the gate terminal thereof. Therefore, a voltage difference Vgd between the gate and drain terminals may become 0.9V (=3.3V-2.4V), a voltage difference Vgs between the gate and source terminals may become 0.5V (=2.4V-1.9V), and a voltage difference Vds between the drain and source terminals may become 1.4V (=3.3V-1.9V). That is, the above voltage differences among the gate, drain, and source terminals of the second NMOS transistor NM2 may have voltage levels in a range of 1.98V or less, which corresponds to the reliability guarantee condition for the low voltage transistor. Similarly, voltage differences among the gate, drain, and source terminals of each of the third NMOS transistor NM3, the first PMOS transistor PM1, and the fourth NMOS transistor NM4 may have voltage levels in a range of 1.98V or less, which corresponds to the reliability guarantee condition for the low voltage transistor.

The fifth NMOS transistor NM5 may receive the third control voltage V_CTR3 of 2.5V through the gate terminal thereof. Therefore, a voltage difference Vgd between the gate and drain terminals may become 0.8V (=3.3V-2.5V), a voltage difference Vgs between the gate and source thereof may become 0.5V (=2.5V-2V), and a voltage difference Vds between the drain and source terminals may become 1.3V (=3.3V-2V). That is, the above voltage differences among the gate, drain, and source terminals of the fifth NMOS transistor NM5 may have voltage levels in a range of 1.98V or less, which corresponds to the reliability guarantee condition for the low voltage transistor. Similarly, voltage differences among the gate, drain, and source terminals of the sixth NMOS transistor NM6 may have voltage levels in a range of 1.98V or less, which corresponds to the reliability guarantee condition for the low voltage transistor.

In particular, in case of the fifth NMOS transistor NM5, a current Ids flowing from the drain terminal to the source terminal thereof may be maximized because the voltage level of the third control voltage V_CTR3 is 2.5V. That is, the electrostatic discharge circuit 300 in accordance with the present embodiment may maximize the current Ids flowing from the drain terminal to the source terminal of the fifth NMOS transistor NM5, thereby maximizing the discharge efficiency for the static electricity.

The electrostatic discharge circuit 300 in accordance with the present embodiment may further include a reverse discharge circuit 350.

Referring to FIG. 2, the reverse discharge circuit 350 may be configured to discharge static electricity, contained in the ground voltage VSS, to the supply voltage terminal. The reverse discharge circuit 350 may be configured as a diode D coupled between the ground voltage terminal and the supply voltage terminal.

The electrostatic discharge circuit 300 in accordance with the present embodiment may perform a discharge operation on not only the static electricity contained in the supply voltage VDDH but also the static electricity contained in the ground voltage VSS.

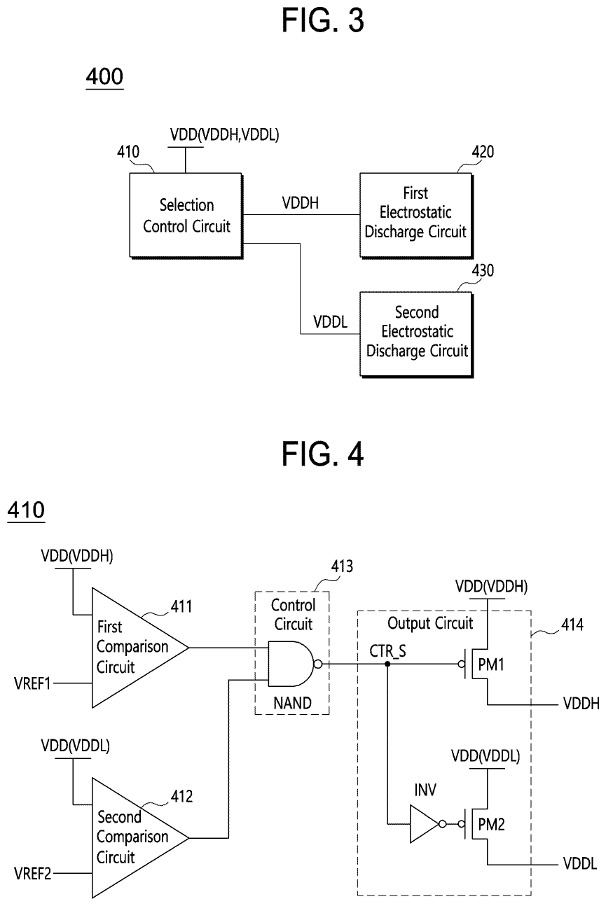

FIG. 3 is a block diagram illustrating an electrostatic discharge control system 400 in accordance with an embodiment.

Referring to FIG. 3, the electrostatic discharge control system 400 may be configured to perform a discharge operation on static electricity contained in multiple supply voltages in an integrated circuit. Hereafter, for convenience of description, the case in which a supply voltage terminal VDD receives a first supply voltage VDDH having one of approximately 3.3V+10%, approximately 2.5V+10%, and approximately 1.8V+10%, which correspond to high voltages, and receives a second supply voltage VDDL having one of approximately 1.8V+10%, approximately 1.2V+10%, and approximately 0.8V+10%, which correspond to low voltages. When the first supply voltage VDDH of 3.3V is applied to the supply voltage terminal VDD, the electrostatic discharge control system 400 may perform the discharge operation on static electricity contained in the first supply voltage VDDH. Furthermore, when the second supply voltage VDDL of 1.8V is applied to the supply voltage terminal VDD, the electrostatic discharge control system 400 may perform the discharge operation on static electricity contained in the second supply voltage VDDL. More specifically, the electrostatic discharge control system 400 may include a selection control circuit 410, a first electrostatic discharge circuit 420, and a second electrostatic discharge circuit 430.

The selection control circuit 410 may be configured to selectively control the first and second electrostatic discharge circuit 420 and 430 based on a supply voltage applied to the supply voltage terminal VDD between the first and second supply voltages VDDH and VDDL. The selection control circuit 410 may be designed to selectively activate the first and second electrostatic discharge circuits 420 and 430. For example, the selection control circuit 410 may selectively provide the first and second supply voltages VDDH and VDDL to the first and second electrostatic discharge circuits 420 and 430. That is, the selection control circuit 410 may provide the first supply voltage VDDH to the first electrostatic discharge circuit 420, and provide the second supply voltage VDDL to the second electrostatic discharge circuit 430. The first electrostatic discharge circuit 420 may be activated based on the first supply voltage VDDH provided thereto. The second electrostatic discharge circuit 430 may be activated based on the second supply voltage VDDL provided thereto.

FIG. 4 illustrates the selection control circuit 410 of FIG. 3.

Referring to FIG. 4, the selection control circuit 410 may include a first comparison circuit 411, a second comparison circuit 412, a control circuit 413, and an output circuit 414.

The first comparison circuit 411 may be configured to compare a supply voltage transferred to the supply voltage terminal VDD to a first reference voltage VREF1 corresponding to the first supply voltage VDDH. When the supply voltage applied to the supply voltage terminal VDD is lower than the first supply voltage VDDH, the first comparison circuit 411 may generate a first comparison signal having a logic low level. When the first supply voltage VDDH is applied to the supply voltage terminal VDD, the first comparison circuit 411 may generate the first comparison signal having a logic high level.

The second comparison circuit 412 may be configured to compare a supply voltage transferred to the supply voltage terminal VDD to a second reference voltage VREF2 corresponding to the second supply voltage VDDL. When the supply voltage applied to the supply voltage terminal VDD is lower than the second supply voltage VDDL, the second comparison circuit 412 may generate a second comparison signal having a logic low level. When the second supply voltage VDDL is applied to the supply voltage terminal VDD, the second comparison circuit 412 may generate the second comparison signal having a logic high level.

The control circuit 413 may be configured to generate a selection control signal CTR_S based on the first and second comparison signals of the first and second comparison circuits 411 and 412. The control circuit 413 may include a NAND gate NAND. The NAND gate NAND may receive the first and second comparison signals of the first and second comparison circuits 411 and 412, perform a NAND operation on the received signals, and output the selection control signal CTR_S.

The output circuit 414 may selectively output, as an output voltage, the first or second supply voltage VDDH or VDDL in response to the selection control signal CTR_S. More specifically, the output circuit 414 may include a first PMOS transistor PM1, an inverter INV, and a second PMOS transistor PM2.

The first PMOS transistor PM1 may receive the selection control signal CTR_S through a gate terminal thereof. The first PMOS transistor PM1 may be turned on when the selection control signal CTR_S has a logic low level. When the first PMOS transistor PM1 is turned on, the first supply voltage VDDH applied to the supply voltage terminal VDD may be outputted as the output voltage. The inverter INV may invert the selection control signal CTR_S and output an inverted selection control signal. Then, the second PMOS transistor PM2 may receive the inverted selection control signal through a gate terminal thereof. The second PMOS transistor PM2 may be turned on when the inverted selection control signal has a logic low level. When the second PMOS transistor PM2 is turned on, the second supply voltage VDDL applied to the supply voltage terminal VDD may be outputted as the output voltage.

Hereafter, a circuit operation of the selection control circuit 410 will be described with reference to FIG. 4.

In the following descriptions, the case in which the second supply voltage VDDL corresponding to a low voltage is applied to the supply voltage terminal VDD will be taken as an example.

The second comparison circuit 412 may receive the second supply voltage VDDL, compare the second supply voltage VDDL to the second reference voltage VREF2, and output the second comparison signal having the logic high level. At this time, the first comparison circuit 411 may generate the first comparison output signal having the logic low level because the first reference voltage VREF1 has a higher voltage level than the second supply voltage VDDL applied to the supply voltage terminal VDD. Then, the NAND gate NAND may output the selection control signal CTR_S having the logic high level based on the first comparison signal having the logic low level and the second comparison signal having the logic high level. Thus, the second PMOS transistor PM2 may be turned on in response to the selection control signal CTR_S having the logic high level, and output the second supply voltage VDDL as the output voltage. At this time, the first PMOS transistor PM1 may maintain a turn-off state.

Next, the case in which the first supply voltage VDDH corresponding to a high voltage is applied to the supply voltage terminal VDD will be described as follows.

The first comparison circuit 411 may receive the first supply voltage VDDH, compare the first supply voltage VDDH to the first reference voltage VREF1, and output the first comparison signal having the logic high level. At this time, the second comparison circuit 412 may generate the second comparison signal having the logic high level because the first supply voltage VDDH applied to the supply voltage terminal VDD has a higher voltage level than the second reference voltage VREF2. Then, the NAND gate NAND may output the selection control signal CTR_S having the logic low level based on the first comparison signal having the logic high level and the second comparison signal having the logic high level. Thus, the first PMOS transistor PM1 may be turned on in response to the selection control signal CTR_S having the logic low level, and output the first supply voltage VDDH as the output voltage. At this time, the second PMOS transistor PM2 may maintain a turn-off state.

When the first supply voltage VDDH is applied to the supply voltage terminal VDD, the selection control circuit 410 having the above-described configuration may provide the first supply voltage VDDH to the first electrostatic discharge circuit 420 of FIG. 3. On the other hand, when the second supply voltage VDDL is applied to the supply voltage terminal VDD, the selection control circuit 410 may provide the second supply voltage VDDL to the second electrostatic discharge circuit 430 of FIG. 3.

Referring back to FIG. 3, the first electrostatic discharge circuit 420 may be activated by the first supply voltage VDDH received from the selection control circuit 410. The first electrostatic discharge circuit 420 may perform a discharge operation on static electricity contained in the first supply voltage VDDH. The first electrostatic discharge circuit 420 may correspond to the electrostatic discharge circuit 300 of FIGS. 1 and 2. That is, the first electrostatic discharge circuit 420 may include the control voltage generation circuit 310, the electrostatic detection circuit 320, the driving control circuit 330, and the discharge driving circuit 340 described with reference to FIGS. 1 and 2.

On the other hand, the second electrostatic discharge circuit 430 may be activated by the second supply voltage VDDL received from the selection control circuit 410. The second electrostatic discharge circuit 430 may perform a discharge operation on static electricity contained in the second supply voltage VDDL.

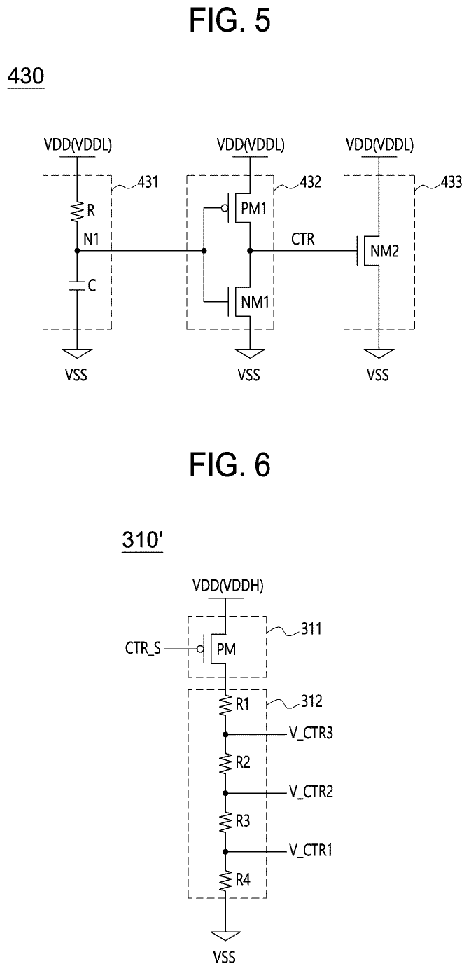

FIG. 5 is a circuit diagram illustrating the second electrostatic discharge circuit 430 of FIG. 3.

Referring to FIG. 5, the second electrostatic discharge circuit 430 may include a detection circuit 431, a driving circuit 432, and a discharge circuit 433. The second electrostatic discharge circuit 430 may receive the second supply voltage VDDL through the supply voltage terminal VDD.

The detection circuit 431 may be configured to detect static electricity contained in the second supply voltage VDDL. The detection circuit 431 may include a resistor R and a capacitor C, which are coupled in series between the supply voltage terminal VDD and the ground voltage terminal.

The driving circuit 432 may be configured to generate a control signal CTR based on an output signal of the detection circuit 431. The driving circuit 432 may include a first PMOS transistor PM1 and a first NMOS transistor NM1, which are coupled in series between the supply voltage terminal VDD and the ground voltage terminal.

The discharge circuit 433 may be configured to form a discharge path for the second supply voltage VDDL in response to the control signal CTR. The discharge circuit 433 may include a second NMOS transistor NM2 coupled between the supply voltage terminal VDD and the ground voltage terminal.

The second electrostatic discharge circuit 430 may receive the second supply voltage VDDL and perform a discharge operation on the second supply voltage VDDL. The first and second NMOS transistors NM1 and NM2 and the first PMOS transistor PM1 may be low voltage transistors.

Hereafter, overall circuit operations of the electrostatic discharge control system 400 of FIG. 3 will be described with reference to FIGS. 3 to 5.

First, the case in which the first supply voltage VDDH corresponding to a high voltage is applied to the supply voltage terminal VDD will be described as follows.

As described above, the selection control circuit 410 of FIG. 4 may output the first supply voltage VDDH as the output voltage when the first supply voltage VDDH is applied to the supply voltage terminal VDD. Therefore, the first electrostatic discharge circuit 420 may be activated, and the second electrostatic discharge circuit 430 may be inactivated. Then, the first electrostatic discharge circuit 420 of FIG. 3 receiving the first supply voltage VDDH may perform the discharge operation described with reference to FIG. 2. Therefore, static electricity contained in the first supply voltage VDDH may be discharged to the ground voltage VSS.

Next, the case in which the second supply voltage VDDL corresponding to a low voltage is applied to the supply voltage terminal VDD will be described as follows.

As described above, the selection control circuit 410 of FIG. 4 may output the second supply voltage VDDL as the output voltage when the second supply voltage VDDL is applied to the supply voltage terminal VDD. Therefore, the first electrostatic discharge circuit 420 may be inactivated, and the second electrostatic discharge circuit 430 may be activated.

Referring to FIG. 5, when no static electricity is contained in the second supply voltage VDDL, a first node N1 of the detection circuit 431 may have a voltage level corresponding to the second supply voltage VDDL because the capacitor C is opened. That is, the first node N1 may have a logic high level. Then, the driving circuit 432 may generate the control signal CTR having a logic low level in response to the logic high level on the first node N1, which is the output signal of the detection circuit 431. At this time, the second NMOS transistor NM2 of the discharge circuit 433 may maintain a turn-off state in response to the control signal CTR having the logic low level.

When static electricity is contained in the second supply voltage VDDL, the first node N1 of the detection circuit 431 may have a voltage level corresponding to the ground voltage VSS because the capacitor C is shorted. That is, the first node N1 may have a logic low level. Then, the driving circuit 432 may generate the control signal CTR having a logic high level in response to the logic low on the first node N1, which is the output signal of the detection circuit 431. Then, the second NMOS transistor NM2 of the discharge circuit 433 may be turned on in response to the control signal CTR having the logic high level. Therefore, the static electricity contained in the second supply voltage VDDL may be discharged to the ground voltage VSS.

As described above, when the second supply voltage VDDL corresponding to a low voltage is applied to the supply voltage terminal VDD, the second electrostatic discharge circuit 430 may be activated. In this case, the first electrostatic discharge circuit 420 may be inactivated. For this operation, the control voltage generation circuit 310 of FIG. 2 may be modified to have the same configuration as FIG. 6. Before description, the control voltage generation circuit 310 may be inactivated when the second supply voltage VDDL is applied to the supply voltage terminal VDD.

FIG. 6 is a circuit diagram illustrating a control voltage generation circuit 310′ in accordance with another embodiment.

Referring to FIG. 6, the control voltage generation circuit 310′ may include a transfer circuit 311 and a voltage dividing circuit 312.

The transfer circuit 311 may be configured to transfer the first supply voltage VDDH received through the supply voltage terminal VDD in response to the selection control signal CTR_S. The transfer circuit 311 may include a PMOS transistor PM which has source and drain terminals coupled between the supply voltage terminal VDD and the voltage dividing circuit 312 and a gate terminal configured to receive the selection control signal CTR_S. The selection control signal CTR_S may correspond to the selection control signal CTR_S of FIG. 4.

The voltage dividing circuit 312 may be configured to receive a voltage transferred through the transfer circuit 311, and generate the first to third control voltages V_CTR1 to V_CTR3. The voltage dividing circuit 312 may include first to fourth resistors R1 to R4 which are coupled in series between the PMOS transistor PM and the ground voltage terminal.

Referring to FIGS. 4 and 6, the circuit operation of the control voltage generation circuit 310′ will be described as follows.

When the first supply voltage VDDH corresponding to a high voltage is applied to the supply voltage terminal VDD, the control circuit 413 of FIG. 4 may generate the selection control signal CTR_S having the logic low level. Then, the PMOS transistor PM of FIG. 6 may be turned on in response to the selection control signal CTR_S having the logic low level. Therefore, when the first supply voltage VDDH is applied to the supply voltage terminal VDD, the control voltage generation circuit 310′ may generate the first to third control voltages V_CTR1 to V_CTR3 through a voltage division operation. Since the voltage division operation for generating the first to third control voltages V_CTR1 to V_CTR3 and the discharge operation using the first to third control voltages V_CTR1 to V_CTR3 have been sufficiently described with reference to FIG. 2, the detailed descriptions thereof will be omitted herein.

When the second supply voltage VDDL corresponding to a low voltage is applied to the supply voltage terminal VDD, the selection control signal CTR_S may have the logic high level. The PMOS transistor PM of FIG. 6 may be turned off in response to the selection control signal CTR_S having the logic high level. Therefore, the control voltage generation circuit 310′ may be inactivated when the second supply voltage VDDL is applied to the supply voltage terminal VDD. Since the first to third control voltages V_CTR1 to V_CTR3 become to have a logic low level when the control voltage generation circuit 310′ is inactivated, the electrostatic detection circuit 320, the driving control circuit 330, and the discharge driving circuit 340 of FIG. 2, which are included in the first electrostatic discharge circuit 420 of FIG. 3, may also be inactivated.

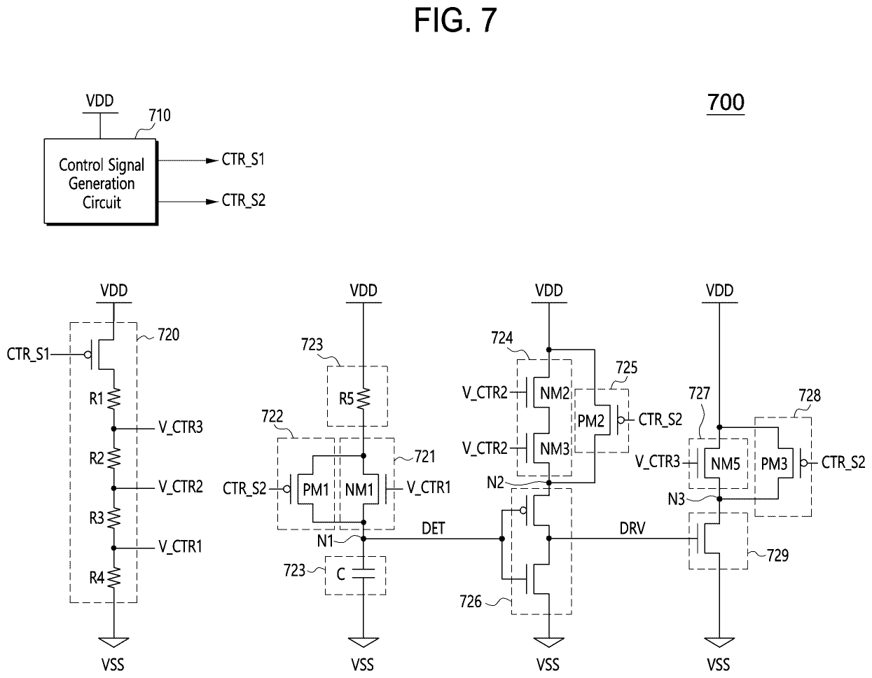

FIG. 7 is a block diagram illustrating an electrostatic discharge control system 700 in accordance with another embodiment.

Referring to FIG. 7, the electrostatic discharge control system 700 may be configured to control a discharge operation on static electricity contained in multiple supply voltages in an integrated circuit which receives the multiple supply voltages through a supply voltage terminal VDD. In the electrostatic discharge control system 700, a first supply voltage VDDH or a second supply voltage VDDL may be applied to the supply voltage terminal VDD as in the electrostatic discharge control system 400 of FIG. 3.

The electrostatic discharge control system 700 may include a control signal generation circuit 710, a control voltage generation circuit 720, a first setup circuit 721, a first transfer circuit 722, a common detection circuit 723, a second setup circuit 724, a second transfer circuit 725, a common driving circuit 726, a third setup circuit 727, a third transfer circuit 728, and a common discharge circuit 729.

The control signal generation circuit 710 may be configured to generate first and second selection control signals CTR_S1 and CTR_S2 based on one supply voltage of the first and second supply voltages VDDH and VDDL, which is applied to the supply voltage terminal VDD. The first and second selection control signals CTR_S1 and CTR_S2 may have an inverse relationship. The first and second selection control signals CTR_S1 and CTR_S2 may be transferred through signal lines separated from each other. In another embodiment, the first and second selection control signals CTR_S1 and CTR_S2 may be transferred through the same signal line, and the second selection control signal CTR_S2 may be an inverted signal of the first selection control signal CTR_S1, or vice versa.

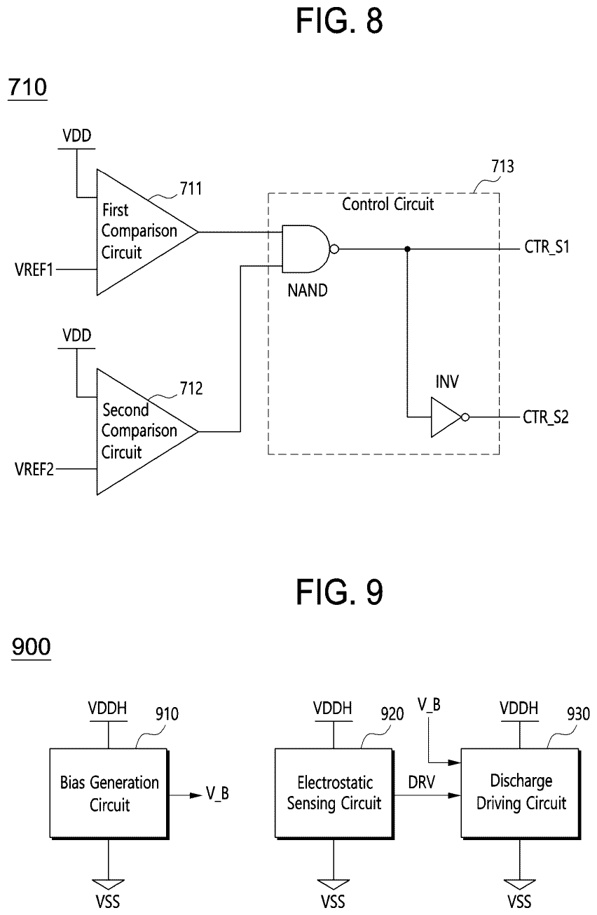

FIG. 8 illustrates the control signal generation circuit 710 of FIG. 7.

Referring to FIG. 8, the control signal generation circuit 710 may include a first comparison circuit 711, a second comparison circuit 712, and a control circuit 713. The control signal generation circuit 710 may have a similar configuration to the selection control circuit 410 of FIG. 4 except the first and second PMOS transistors PM1 and PM2.

When the first supply voltage VDDH is applied to the supply voltage terminal VDD, the control signal generation circuit 710 may generate the first selection control signal CTR_S1 having a logic low level and the second selection control signal CTR_S2 having a logic high level. On the other hand, when the second supply voltage VDDL is applied to the supply voltage terminal VDD, the control signal generation circuit 710 may generate the first selection control signal CTR_S1 having a logic high level and the second selection control signal CTR_S2 having a logic low level.

Referring back to FIG. 7, the control voltage generation circuit 720 may be activated or inactivated in response to the first selection control signal CTR_S1, and generate first to third control voltages V_CTR1 to V_CTR3 by performing a voltage division operation on the supply voltage transferred through the supply voltage terminal VDD. The control voltage generation circuit 720 may correspond to the control voltage generation circuit 310 of FIG. 6. However, the control voltage generation circuit 720 may receive the first selection control signal CTR_S1 instead of the selection control signal CTR_S, unlike the control voltage generation circuit 310 of FIG. 6.

As described above, the first selection control signal CTR_S1 may have the logic low level when the first supply voltage VDDH is applied to the supply voltage terminal VDD. Therefore, the control voltage generation circuit 720 may be activated when the first supply voltage VDDH is applied to the supply voltage terminal VDD. Thus, the control voltage generation circuit 720 may generate the first to third control voltages V_CTR1 to V_CTR3 by performing the voltage division operation on the first supply voltage VDDH. On the other hand, the first selection control signal CTR_S1 may have the logic high level when the second supply voltage VDDL is applied to the supply voltage terminal VDD. Therefore, the control voltage generation circuit 720 may be inactivated.

The first setup circuit 721, the common detection circuit 723, the second setup circuit 724, the common driving circuit 726, the third setup circuit 727, and the common discharge circuit 729 may correspond to the first setup circuit 321, the common detection circuit 322, the second setup circuit 331, the common driving circuit 332, the third setup circuit 341, and the common discharge circuit 342 of FIG. 2, respectively.

However, the common detection circuit 723, the common driving circuit 726, and the common discharge circuit 729 may be used in common when the first and second supply voltages VDDH and VDDL are applied to the supply voltage terminal VDD. That is, the common detection circuit 723, the common driving circuit 726, and the common discharge circuit 729 may be used for performing a discharge operation on the first supply voltage VDDH and a discharge operation on the second supply voltage VDDL. Therefore, the electrostatic discharge control system 700 in accordance with the present embodiment may minimize a circuit area occupied by a circuit required for performing the discharge operation on multiple supply voltages including the first and second supply voltages VDDH and VDDL.

The first transfer circuit 722 may be coupled in parallel to the first setup circuit 721, and transfer, as a first setup voltage, a supply voltage applied through the supply voltage terminal VDD in response to the second selection control signal CTR_S2. The first transfer circuit 722 may include a first PMOS transistor PM1. The first PMOS transistor PM1 may be coupled between a fifth resistor R5 and a first node N1, and receive the second selection control signal CTR_S2 through a gate terminal thereof.

As described above, when the second supply voltage VDDL is applied to the supply voltage terminal VDD, the second selection control signal CTR_S2 may have the logic low level. The first PMOS transistor PM1 may be turned on in response to the second selection control signal CTR_S2 having the logic low level. At this time, a first NMOS transistor NM1 of the first setup circuit 721 may be turned off in response to the first control voltage V_CTR1 having the logic low level. Therefore, the second supply voltage VDDL may be transferred to the first node N1 through the fifth resistor R5 and the first PMOS transistor PM1.

The second transfer circuit 725 may be coupled in parallel to the second setup circuit 724, and transfer, as a second setup voltage, the supply voltage applied through the supply voltage terminal VDD in response to the second selection control signal CTR_S2. The second transfer circuit 725 may include a second PMOS transistor PM2. The second PMOS transistor PM2 may be coupled between the supply voltage terminal VDD and a second node N2, and receive the second selection control signal CTR_S2 through a gate terminal thereof. Therefore, when the second supply voltage VDDL is applied to the supply voltage terminal VDD, the second PMOS transistor PM2 may be turned on in response to the second selection control signal CTR_S2 having the logic low level. At this time, second and third NMOS transistors NM2 and NM3 may be turned off in response to the second control voltage V_CTR2 having the logic low level. Thus, the second supply voltage VDDL may be transferred to the second node N2 through the second PMOS transistor PM2.

The third transfer circuit 728 may be coupled in parallel to the third setup circuit 727, and transfer, as a third setup voltage, the supply voltage applied through the supply voltage terminal VDD in response to the second selection control signal CTR_S2. The third transfer circuit 728 may include a third PMOS transistor PM3. The third PMOS transistor PM3 may be coupled between the supply voltage terminal VDD and a third node N3, and receive the second selection control signal CTR_S2 through a gate terminal thereof. Therefore, when the second supply voltage VDDL is applied to the supply voltage terminal VDD, the third PMOS transistor PM3 may be turned on in response to the second selection control signal CTR_S2 having the logic low level. At this time, a fifth NMOS transistor NM5 may be turned off based on the third control voltage V_CTR3 having the logic low level. Thus, the second supply voltage VDDL may be transferred to the third node N3 through the third PMOS transistor PM3.

The first to third PMOS transistors PM1 to PM3 may each have a reliability guarantee condition depending on operation characteristics thereof, like the NMOS transistors included in the electrostatic discharge control system 700. That is, low voltage transistors may be used as the first to third PMOS transistors PM1 to PM3.

In short, the NMOS transistors and the PMOS transistors in the electrostatic discharge control system 700 in accordance with the present embodiment may be low voltage transistors. Furthermore, although the first supply voltage VDDH or the second supply voltage VDDL is applied to the supply voltage terminal VDD, the electrostatic discharge control system 700 may perform a discharge operation on static electricity contained in the first supply voltage VDDH or the second supply voltage VDDL. The electrostatic discharge control system 700 may further include the common detection circuit 723, the common driving circuit 726, and the common discharge circuit 729 that are used when any of the first and second supply voltages VDDH and VDDL is applied to the voltage supply terminal VDD.

As described above, the electrostatic discharge control system 700 may perform the discharge operation on both of the first and second supply voltages VDDH and VDDL. Therefore, the electrostatic discharge control system 700 can be implemented in the minimum circuit area.

FIG. 9 is a block diagram illustrating an electrostatic discharge circuit 900 in accordance with another embodiment.

Referring to FIG. 9, the electrostatic discharge circuit 900 may be configured to sense and discharge static electricity contained in a supply voltage VDDH. More specifically, the electrostatic discharge circuit 900 may include a bias generation circuit 910, an electrostatic sensing circuit 920, and a discharge driving circuit 930.

The bias generation circuit 910 may be configured to generate a bias voltage V_B. The bias generation circuit 910 may be coupled between a supply voltage terminal to which the supply voltage VDDH is applied and a ground voltage terminal to which the ground voltage VSS is applied. The bias generation circuit 910 may correspond to the control voltage generation circuit 310 of FIG. 1. Thus, the bias voltage V_B may correspond to one of the first to third control voltages V_CTR1 to V_CTR3 of FIG. 1.

The electrostatic sensing circuit 920 may be configured to sense static electricity contained in the supply voltage VDDH and generate a driving control signal DRV. The electrostatic sensing circuit 920 may include the electrostatic detection circuit 320 and the driving control circuit 330 of FIG. 1.

The discharge driving circuit 930 may be configured to set a setup voltage based on the bias voltage V_B, and perform a discharge operation on static electricity contained in the setup voltage based on the driving control signal DRV. The discharge driving circuit 930 may correspond to the discharge driving circuit 340 of FIG. 1. However, the discharge driving circuit 930 of FIG. 9 may receive the bias voltage V_B instead of the third control voltage V_CTR3 of FIG. 1, unlike the discharge driving circuit 340 of FIG. 1.

The electrostatic discharge circuit 900 in accordance with the present embodiment may set the setup voltage of the discharge driving circuit 930 in response to the bias voltage V_B. Furthermore, the electrostatic discharge circuit 900 may perform a discharge operation on the static electricity contained in the setup voltage.

In accordance with the above-described embodiments, the electrostatic discharge circuit and the electrostatic discharge control system can protect internal circuits of an integrated circuit from the static electricity contained in the supply voltage, thereby guaranteeing a stable circuit operation.

Furthermore, low voltage transistors may be used to implement the electrostatic discharge circuit and the electrostatic discharge control system. Thus, it is possible to minimize the circuit areas of the electrostatic discharge circuit and the electrostatic discharge control system.

In embodiments, as an operation speed of an integrated circuit device including a plurality of semiconductor elements increases, a driving voltage of the integrated circuit device also decreases. For example, an interface voltage used as input/output power of the integrated circuit device is changing from 1.8V to 1.2V. When the interface voltage is decreased, power consumption, noise, and a pad capacitance of the integrated circuit device may be reduced.

For example, an interface voltage may provide to an interface circuit connected between a semiconductor memory device and a memory controller configured to control the semiconductor memory device, as power voltage. As the semiconductor memory device is driven at a low voltage, for example, 0.8V to 1.2V, the interface circuit also requires a low interface voltage. So transistors constituting the interface circuit are gradually changed from a transistor having a thick gate oxide (hereinafter, a high voltage transistor) to a transistor having a thin gate oxide (hereinafter, a low voltage transistor). As the low voltage transistors are applied to the interface circuit, the power consumption of the integrated circuit device including the interface circuit and an area of the interface circuit may be reduced.

Generally, the interface circuit may receive both a low voltage corresponding to 0.8V and a high voltage (or medium voltage) corresponding to 1.2V˜1.8V. At this time, if the interface circuit is composed of low voltage transistors driven at 0.8V, reliability of the low voltage transistors constituting the interface circuit must be maintained even when the high voltage (1.2V to 1.8V) greater than its driving voltage is received.

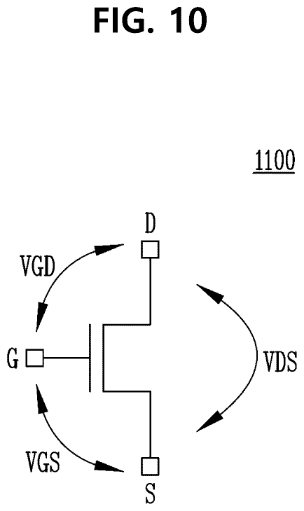

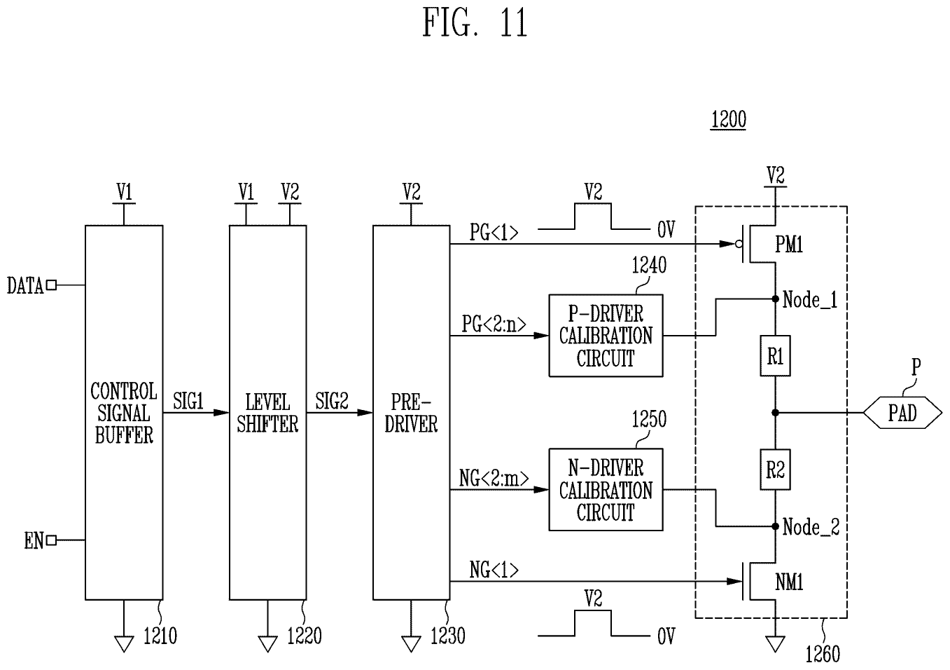

FIG. 10 is a view illustrating an operation condition of a low voltage transistor in accordance with example embodiments.

In order for the low voltage transistor 1100 to stably operate, internal voltages of the low voltage transistor 1100, for example, a gate-source voltage VGS, a gate-drain voltage VGD, and a drain-source voltage VDS are required to satisfy reliability condition. For example, a range for guaranteeing reliabilities of a gate-source voltage VGS, a gate-drain voltage VGD and a drain-source voltage VDS of the low voltage transistor may be about 1.1 times to about 1.2 times of the driving voltage of the low voltage transistor 1100.

For example, when the driving voltage of the low voltage transistor 1100 may be set about 0.8V, the gate-source voltage VGS, the gate-drain voltage VGD and the drain-source voltage VDS (hereinafter, internal voltages) of the low voltage transistor 1100 may be within about 0.88V to about 0.96V to guarantee the reliability of the low voltage transistor 1100.

Hereinafter, a voltage of about 1.1 to 1.2 times of the driving voltage may be referred to as maximum operating voltage.

FIG. 11 is a circuit diagram illustrating an output driving circuit 1200 according to an embodiment of the present disclosure.

Referring to FIG. 2, the output driving circuit 1200 includes a control signal buffer 1210, a level shifter 1220, a pre-driver 1230, a first driver calibration circuit (e.g., a P-driver calibration circuit) 1240, a second driver calibration circuit (e.g., an N-driver calibration circuit 1250), and a driver (e.g., a pull-up-pull-down driver) 1260. The pull-up-pull-down driver 1260 includes a PMOS transistor PM1, an NMOS transistor NM1, a first resistor R1, and a second resistor R2. The control signal buffer 1210 receives a data signal DATA and an enable signal EN, and outputs a first signal SIG1. The control signal buffer 1210 may be operated by a first power voltage V1. Therefore, the first signal SIG1 may be a signal having a voltage range between 0V and the first power voltage V1. In an embodiment, the first power voltage V1 may be a voltage having any value in a range of 0.8V to 1V.

The level shifter 1220 receives the first signal SIG1 and level-shifts the first signal SIG1 to generate a second signal SIG2. The level shifter 1220 may be operated by the first power voltage V1 and a second power voltage V2. The second power voltage V2 may be an external voltage having a voltage level greater than that of the first power voltage V1. The first power voltage V1 may be an internal voltage. Therefore, the second signal SIG2 may be a signal having a voltage range between 0V and the second power voltage V2. In an embodiment, the second power voltage V2 may be a voltage having any value in a range of 1.2V to 1.8V. That is, in example embodiments, the first power voltage V1 may be a low voltage and the second power voltage may be a high voltage V2 higher than the first power voltage.

The pre-driver 1230 outputs a plurality of PMOS gate signals PG<1: n> and a plurality of NMOS gate signals NG<1: m> based on the second signal SIG2. A first PMOS gate signal PG<1>among the PMOS gate signals PG<1: n> is applied to the PMOS transistor PM1. Second to n-th PMOS gate signals PG<2: n>among the PMOS gate signals PG<1: n> are applied to the P-driver calibration circuit 1240. A first NMOS gate signal NG<1>among the NMOS gate signals NG<1: n> is applied to the NMOS transistor NM1. Second to n-th NMOS gate signals NG<2: n>among the NMOS gate signals NG<1: n> are applied to the N-driver calibration circuit 1250. That is, the pre-driver 1230 may output the PMOS gate signals PG<1: n> and the NMOS gate signals NG<1: m> of a code form.

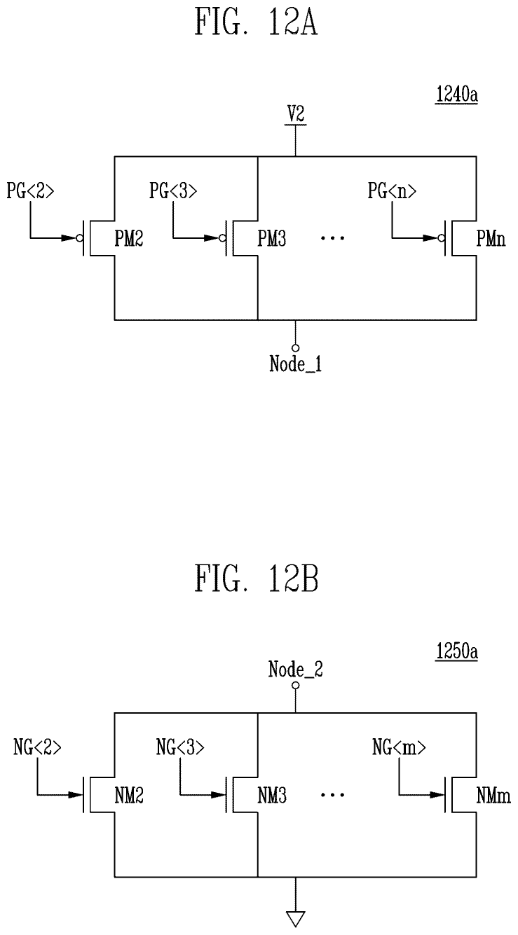

The P-driver calibration circuit 1240 may be a circuit for calibrating an impedance of a first node NODE_1. An embodiment of the P-driver calibration circuit 1240 is described later with reference to FIG. 12A. Meanwhile, the N-driver calibration circuit 1250 may be a circuit for calibrating an impedance of a second node NODE_2. An embodiment of the N-driver calibration circuit 1250 is described later with reference to FIG. 12B.

Meanwhile, the pre-driver 1230 may operate by the second power voltage V2. Therefore, the PMOS gate signals PG<1: n> and the NMOS gate signals NG<1: m> may be signals each having a voltage range between 0V and the second power voltage V2. In particular, as shown in FIG. 11, the first PMOS gate signal PG<1>applied to the PMOS transistor PM1 and the first NMOS gate signal NG<1>applied to the NMOS transistor NM1 may be signals having a voltage range between 0V and the second power voltage V2 (for example, 1.8V).

Thus, the internal voltages of the PMOS transistor PM1 and the NMOS transistor NM1, gate-source voltages VGS, gate-drain voltages VGD and drain-source voltages VDS of the PMOS transistor PM1 and the NMOS transistor NM1 in FIG. 11 may be above the maximum operating voltage of the low voltage transistor so that reliability of the PMOS transistor PM1 and the NMOS transistor NM1 might not be guaranteed.

FIG. 12A is a circuit diagram illustrating a P-driver calibration circuit 1240a suitable for use as the P-driver calibration circuit 1240 of FIG. 11, according to an embodiment of the present disclosure. Referring to FIG. 12A, the P-driver calibration circuit includes second to n-th PMOS transistors PM2 to PMn. The second to n-th PMOS transistors PM2 to PMn may be connected in parallel between the second power voltage V2 and the first node NODE_1. Meanwhile, the second to n-th PMOS gate signals PG<2: n> may be applied to gate terminals of the second to n-th PMOS transistors PM2 to PMn. Accordingly, the impedance of the first node NODE_1 may be calibrated by the second to n-th PMOS gate signals PG<2: n>output in the code form.

FIG. 12B is a circuit diagram illustrating an N-driver calibration circuit 1250a suitable for use as the N-driver calibration circuit 1250 of FIG. 11, according to an embodiment of the present disclosure.

Referring to FIG. 12B, the N-driver calibration circuit includes second to m-th NMOS transistors NM2 to NMm. The second to m-th NMOS transistors NM2 to NMm may be connected in parallel between the second node NODE_2 and a ground. Meanwhile, the second to m-NMOS gate signals NG<2: m> may be applied to gate terminals of the second to m-th NMOS transistors NM2 to NMm. Accordingly, the impedance of the second node NODE_2 may be calibrated by the second to m-th NMOS gate signals NG<2: m>output in the code form.

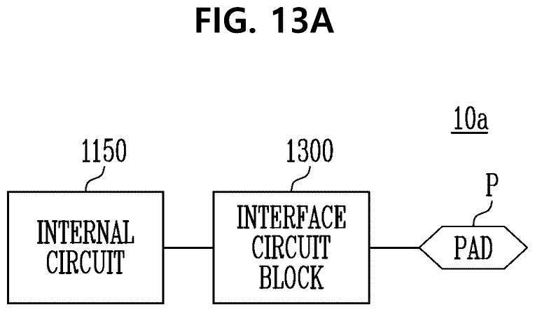

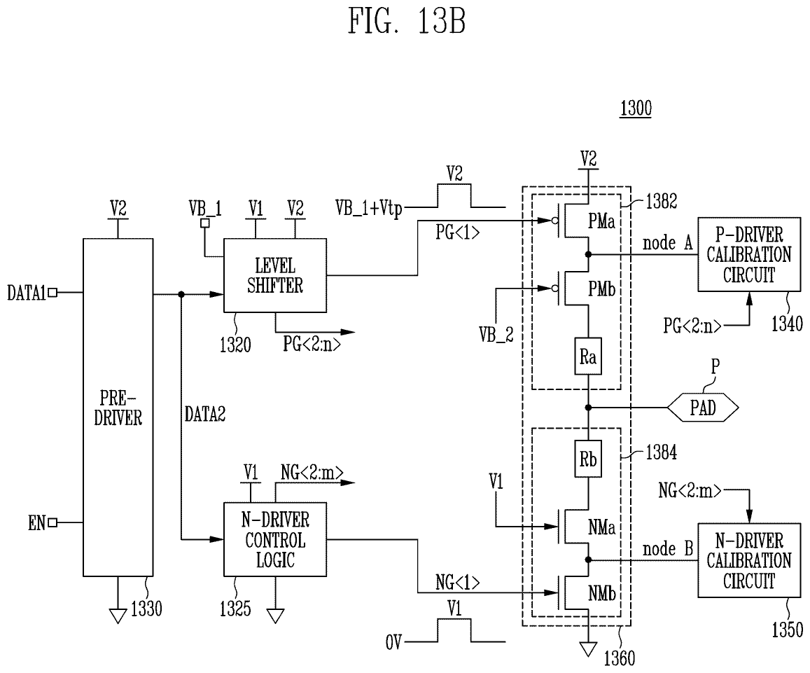

FIG. 13A is a block diagram illustrating a semiconductor output circuit device in accordance with example embodiments and FIG. 13B is a block diagram illustrating the interface circuit block in FIG. 13A.

Referring to FIG. 13A, a semiconductor output circuit device 10a may include an internal circuit block 1150, an interface circuit block 1300 and a pad P.

The internal circuit block 1150 may include a memory cell array and a control circuit configured to drive the memory cell array. Alternatively, the internal circuit block 1150 may include various circuits as well as the memory cell array and the control circuit. For example, the internal circuit block 1150 may receive a first power voltage to output a data signal having the first power voltage level.

The interface circuit block 1300 may include a circuit configured to control a characteristic difference between the internal circuit block 1150 and the pad P. In example embodiments, the interface circuit block 1300 may control a difference between an input/output signal of the internal circuit block 1150 and an input/output signal of the pad P. The interface circuit block 1300 may include a plurality of low voltage transistors driven by the first power voltage V1. The interface circuit block 1300 may receive a second power voltage V2 greater than the first power voltage as a power source. The interface circuit block 1300 may receive a plurality of control voltages for controlling an internal voltage of the low voltage transistors of no more than the maximum operating voltage. The interface circuit block 1300 may convert a data signal having the first power voltage level into a data signal having the second power voltage level. The interface circuit block 1300 may then provide the pad P with the data signal having the second power voltage level.

Another type of preferred output driving circuit is disclosed in U.S. patent application Ser. No. 17/073,964, filed Oct. 19, 2020 and entitled, “OUTPUT DRIVING CIRCUIT,” the entire disclosure of which is incorporated herein by reference.

Referring to FIG. 13B, the interface circuit block 1300 may include a pre-driver 1330, a level shifter 1320, a driver control logic (e.g., an N-driver control logic) 1325, a first driver calibration circuit (e.g., a P-driver calibration circuit) 1340, a second driver calibration circuit (e.g., an N-driver calibration circuit) 1350, and an output driver 1360.

The pre-driver 1330, the level shifter 1320, the N-driver control logic 1325, the P-driver calibration circuit 1340, the N-driver calibration circuit 1350 and the output driver 1360 may include a plurality of low voltage transistors, respectively. For example, the low voltage transistors of the pre-driver 1330, the low voltage transistors of the level shifter 1320, the low voltage transistors of the N-driver control logic 1325, the low voltage transistors of the P-driver calibration circuit 1340, the low voltage transistors of the N-driver calibration circuit 1350 and the low voltage transistors of the output driver 1360 may be driven at the first power voltage V1. Even if, the interface circuit block 1300 composed of the low voltage transistors receives the second power voltage V2 greater than the first power voltage V1 and the maximum operating voltage, at least one control bias may be applied to selected electrodes of specific low transistors of the interface circuit block 1300, to guarantee the reliability of the low voltage transistors

The pre-driver 1330 may receive a first data signal DATA1 and an enable signal EN to output a second data signal DATA2. Since the pre-driver 1330 may include at least one low voltage transistor, the pre-driver 1330 may be driven at the first power voltage V1. Thus, the second data signal DATA2 of the pre-driver 1330 may have a voltage level of about 0V to about 1V corresponding to a range of the first power voltage V1.

The second data signal DATA2 and the first data signal DATA1 may be substantially same. For example, the second data signal may be generated based on the first data signal DATA1.

In example embodiments, the first data signal DATA1 may be provided from the internal circuit 1150. The pre-driver 1330 may buffer the first data signal DATA1 using the first power voltage V1 to output the second data signal DATA1. For example, the second data signal DATA2 may have a logic level substantially the same as a logic level of the first data signal DATA1. In contrast, the voltage level of the second data signal DATA2 may be different from that of the first data signal DATA1.

The level shifter 1320 may receive the second data signal DATA2 to output a plurality of PMOS gate signals PG<1> and PG<2: n>. The level shifter 1320 may receive the first power voltage V1, the second power voltage V2, as the power source. Further, the level shifter 1320 may receive a first bias voltage VB_1 to generate the control bias.

The level shifter 1320 may output the first PMOS gate signal PG<1> (hereinafter, referred to as a first control bias) based on the first bias voltage VB_1. In example embodiments, a voltage range of the first control bias PG<1> may have about (VB 1+Vtp) to the second power voltage V2. The voltage ‘Vtp’ may be a threshold voltage of the first PMOS transistor PMa. For example, all of the PMOS transistors constituting the interface circuit block 1300 may include the same threshold voltage Vtp. In embodiments, although a source of the first PMOS transistor PMa may directly receive the second power voltage V2 greater than the maximum operating voltage, internal voltages VGS, VGD and VDS of the first PMOS transistor PMa may be between 0V and the maximum operating voltage, because the first control bias PG<1>is applied to a gate of the first PMOS transistor PMa. Thus, the reliability of the first PMOS transistor directly receiving the second power voltage V2 is guaranteed.

Further, the level shifter 1320 may output the second to n-th PMOS gate signals PG<2: n> based on the first bias voltage VB_1. Similarly to the first control bias PG<1>, the level shifter 1320 may output the second to n-th PMOS gate signals PG<2: n>each having a voltage range of (VB_1+Vtp) to V2. The level shifter 1320 may generate the second to n-th PMOS gate signals PG<2: n> as a calibration control signal for controlling the P-driver calibration circuit 1340.

An embodiment of the level shifter 1320 of FIG. 4B is described later with reference to FIG. 5.

The N-driver control logic 1325 may receive the second data signal DATA2 to output a plurality of NMOS gate signals NG<1> and NG<2: m>. The N-driver control logic 1325 may receive the first power voltage V1 as a power source of the N-driver control logic 1325. Thus, the N-driver control logic 1325 may output the NMOS gate signal NG<1: m> having a voltage range between about 0V and the first power voltage V1. Thus, internal voltages VGS, VGD and VDS of the second NMOS transistor NMb receiving the NMOS gate signal NG<1>may be within the maximum operating voltage, because the second NMOS transistor may include the low voltage transistor driven at the first power voltage V1 (for example, about 0V to about 1V).

The output driver 1360 may include a pull-up driver 1382 and a pull-down driver 1384. The pull-up driver 1382 may include a first PMOS transistor PMa, a second PMOS transistor PMb, and a first resistor Ra which are serially connected.

The source of the first PMOS transistor PMa may be connected with a terminal to which the second power voltage V2 may be applied, as above. The drain of the first PMOS transistor PMa may be connected to a node A. The gate of the first PMOS transistor PMa may receive the first control bias PG<1>(VB 1+Vtp)˜ V2) to secure the reliability of the first PMOS transistor PMa. The node A may be connected to the source of the second PMOS transistor PMb and the P-driver calibration circuit 1340 in common.

The source of the second PMOS transistor PMb may be connected to the node A. The drain of the second PMOS transistor PMb may be connected to the first resistor Ra. The gate of the second PMOS transistor PMb may receive the second bias voltage VB_2. In example embodiments, the second PMOS transistor PMb may be maintained in a normally turn-on state. Thus, the second bias voltage VB_2 corresponding to a gate signal of the second PMOS transistor PMb should be set in a range where internal voltages VGS, VGD and VDS of the second PMOS transistor PMb do not exceed the maximum operating voltage. When the pull-down driver 1384 may be driven, the second bias voltage VB_2 may control the voltage level of the node A so that a voltage difference between the voltage of the node A and the first control signal PG<1> may be within the maximum operating voltage.

The first resistor Ra may be connected between the drain of the second PMOS transistor PMb and the pad P. For example, the first resistor Ra may include an electrostatic discharge (ESD) protection resistor. When the interface circuit block 1300 may output an output signal through the pad p, the first resistor Ra may finally control an impedance of the output signal.

The second resistor Rb of the pull-down driver 1384, the first NMOS transistor NMa and the second NMOS transistor NMb may be connected between the pad P and the ground terminal in serial.

The second resistor Rb may be connected between the pad P and the drain of the first NMOS transistor NMa. The second resistor Rb may include an ESD protection circuit as the first resistor Ra. The second resistor Rb may finally control the impedance of the output signal.

The drain of the first NMOS transistor NMa may be connected to the second resistor Rb. The source of the first NMOS transistor NMa may be connected to the node B. The gate of the first NMOS transistor NMa may receive the first power voltage V1. The node B may be connected to the drain of the second NMOS transistor MNb and the N-driver calibration circuit 1340.

A preferred low-voltage and high-voltage tolerant ESD circuit is disclosed in U.S. patent application Ser. No. 17/362,655, filed Jun. 29, 2021 and entitled, “ELECTROSTATIC DISCHARGE CIRCUIT AND ELECTROSTATIC DISCHARGE CONTROL SYSTEM,” the entire disclosure of which is incorporated herein by reference.

The drain of the second NMOS transistor NMb may be connected to the node B. The source of the second NMOS transistor NMb may be connected to the ground terminal. The gate of the second NMOS transistor NMb may receive the first NMOS gate signal NG<1>corresponding to the first power voltage V1. For example, the first power voltage may swing between 0V and V1.

In example embodiments, the first bias voltage VB_1 and the second bias voltage VB_2 may be provided to the interface circuit block 1300 separately from the first and second power voltages V1 and V2, to stabilize the low voltage transistors constituting the interface circuit block 1300. Alternatively, the first bias voltage VB_1 and the second bias voltage VB_2 may be generated in the interface circuit block 1300. In this case, the interface circuit block 1300 may include a regulating circuit for generating the first bias voltage VB_1 and the second bias voltage VB_2 based on the first voltage V1 or the second voltage V2.

The P-driver calibration circuit 1340 is connected to a node NODE_A of the output driver 1360. The N-driver calibration circuit 1350 is connected to a node NODE_B of the output driver 1360.

In FIG. 13B, the P-driver calibration circuit 1340 and the N-driver calibration circuit 1350 may be substantially the same as the P-driver calibration circuit 1240a and the N-driver calibration circuit 1250a shown in FIGS. 12A and 12B, respectively. Therefore, repetitive description of the P-driver calibration circuit 1340 and the N-driver calibration circuit 1350 is omitted. In example embodiments, the P-driver calibration circuit 1240 may be connected to the node A to primarily control the impedance between the interface circuit block 1300 and the pad P. Similarly, the N-driver calibration circuit 1350 may be connected to the node B to primarily control the impedance between the interface circuit block 1300 and the pad P.

In example embodiments, the interface circuit block 1300 may receive the first power voltage V1 and the second power voltage V2. Alternatively, the interface circuit block 1300 may include the low voltage transistors driven by the first power voltage V1

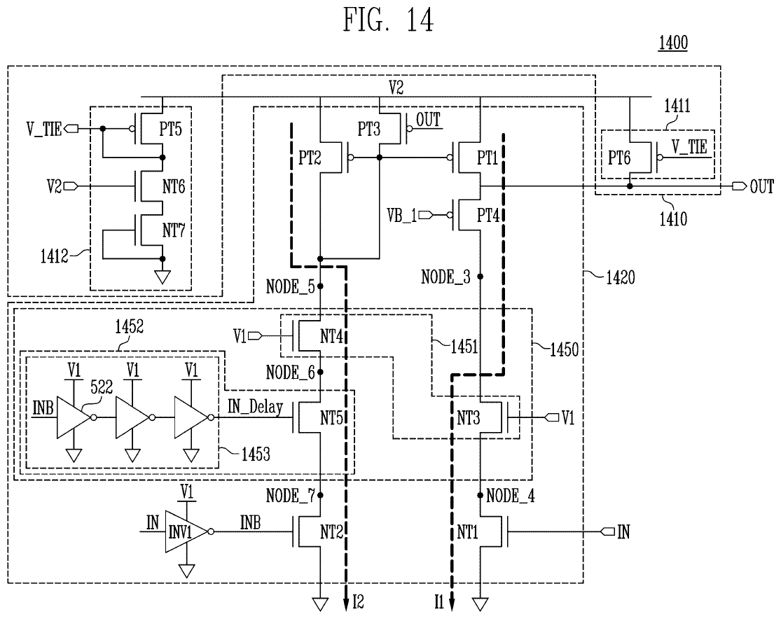

FIG. 14 is a diagram illustrating a configuration of a level shifter 1400 suitable for use as the level shifter 1320 shown in FIG. 13B.

Referring to FIG. 14, the level shifter 1400 may include a current mirror 1420, a first adjustment circuit 1430, and a second adjustment circuit 1410.

The level shifter 1400 according to an embodiment of the present disclosure may further include a third adjustment circuit 1450. The current mirror 1420, the first adjustment circuit 1430,

the second adjustment circuit 1410 and the third adjustment circuit 1450 of example embodiments may include at least one low voltage transistor driven at the first power voltage V1, respectively. Although the level shifter 1400 may include the low voltage transistor, the level shifter 1400 may receive the second power voltage V2 as the power source.

The current mirror 1420 may receive an input signal IN according to the first power voltage V1 and mirror a current corresponding to the second power voltage V2 according to a level of the input signal IN to generate an output signal OUT. The input signal

IN may be the second data signal DATA2 shown in FIG. 13B. In addition, the output signal OUT may be the first PMOS gate signal PG<1>shown in FIG. 13B.

As above, the second power voltage V2 may have a level higher than that of the first power voltage V1.

The current mirror 1420 may include an inverter INV1 and a plurality of switching elements NT1, NT2, PT1, PT2, and PT3. The plurality of switching elements NT1, NT2, PT1, PT2, and PT3 may be implemented as the low voltage transistors driven at the low voltage, for example, 0.8V.

A first current path I1 of the current mirror 1420 may be formed by a plurality of switching elements PT1, PT4, NT3, and NT1.

A second current path 12 of the current mirror 1420 may be formed by a plurality of switching elements PT2, NT4, NT5, and NT2.

The first adjustment circuit 1430 may be connected to an output terminal of the current mirror 1420. For example, the first adjustment circuit 1430 may include a PMOS transistor. The first adjustment circuit 1430 may receive the first bias voltage VB_1 as a gate signal, to adjust internal voltages of the first adjustment circuit 1430. That is, the first bias voltage VB_1 should be set in a range where the internal voltages VGS, VGD and VDS of the first adjustment circuit 1430 do not exceed the maximum operating voltage.

For example, the first adjustment circuit 1430 may be connected to a terminal of the output voltage OUT of the current mirror 1420 and may be configured to adjust a voltage level of the terminal of the output voltage OUT according to the first bias voltage VB_1.

The first adjustment circuit 1430 may include a switching element, for example, the PMOS transistor PT4 in the first current path I1.

The second adjustment circuit 1410 may be connected between the terminal receiving the second power voltage V2 and the output terminal of the current mirror 1420. For example, the second adjustment circuit 1410 may provide the output terminal of the current mirror 1420 with a compensation current corresponding to a current amount of the current mirror 1420.

For example, the second adjustment circuit 1410 may be connected to a terminal of the second power voltage V2 in parallel with the current mirror 1420 and may be configured to adjust the voltage level of the terminal of the output voltage OUT of the current mirror 1420.

The second adjustment circuit 1410 may include an output voltage compensator 1411 and a compensation voltage generator 1412.

The output voltage compensator 1411 may prevent the voltage level of the terminal of the output voltage OUT from being lower than the voltage level increased by the first adjustment circuit 1430 according to a compensation voltage V_TIE.

The compensation voltage generator 1412 may be connected to the terminal of the second power voltage V2 in parallel with the current mirror 1420 to generate the compensation voltage V_TIE.

The second adjustment circuit 1410 may include a plurality of switching elements PT5, PT6, NT6, and NT7.

The third adjustment circuit 1450 may be connected to the first current path and the second current path of the current mirror 1420, and may be configured to adjust a voltage level of the first current path and the second current path and block a leakage current.

The third adjustment circuit 1450 may include a first adjuster 1451 and a second adjuster 1452.

The first adjuster 1451 may adjust current amounts of the first current path I1 and the second current path 12 of the current mirror 1420 in accordance with the first power voltage V1.

The second adjuster 1452 may block the leakage current of the second current path 12 of the current mirror 1420 according to the input signal IN. The second adjuster 1452 may include a delay circuit 1453.

The third adjustment circuit 1450 may include the delay circuit 1453 and a plurality of switching elements NT3, NT4, and NT5.

For example, when the first power voltage V1 may be about 0.8V and the second power voltage V2 may be about 1.2V, the internal voltages of each of the transistors have to maintain under the maximum operating voltage ((1.1˜1.2) X V1) to guarantee the reliability of all the low voltage transistors.

Therefore, the level shifter 1400 according to the embodiment shown in FIG. 14 is designed to satisfy the above-described node voltage difference condition using the first adjustment circuit 1430 and the second adjustment circuit 1410, and additionally, the third adjustment circuit 1450 of the level shifter 1400 is configured to improve stability and a leakage current prevention function.

The first switching element NT1 may include one end connected to a ground terminal, another end connected to a node NODE_4, and a control end receiving the input signal IN.

At this time, one end of the plurality of switching elements NT1, NT2, PT1, PT2, and PT3 may be a source or a drain, another end may be a drain or a source, and a control end may be a gate.

The inverter INV1 may invert the input signal IN to generate an inverted input signal INB.

The second switching element NT2 may include one end connected to the ground terminal, another end connected to a node NODE_7, and a control end receiving the inverted input signal INB.

The third switching element PT1 may include one end connected to the terminal of the second power voltage V2 and another end connected to the terminal of the output voltage OUT.

The fourth switching element PT2 may include one end connected to the terminal of the second power voltage V2 and another end connected to a node NODE_5.

The fifth switching element PT4 may include one end connected to the terminal of the output voltage OUT, another end connected to a node NODE_3, and a control end receiving the first bias voltage VB_1.

As above, the first bias voltage VB_1 may be set in a level for securing the reliability of the fifth switching element PT4 including the low voltage transistor. For example, the first bias voltage VB_1 may be set such that a difference between the output voltage OUT and the first bias voltage VB_1 is below the maximum operating voltage. In embodiments, when the first power voltage V1 may be about 0.8V and the second power voltage V2 may be about 1.2V, the first bias voltage VB_1 may be about 0.12V.

Because the first bias voltage VB_1 may be inputted into the control terminal (i.e., gate) of the fifth switching element PT4, for example, the gate, the output voltage OUT corresponding to the source voltage may have a range of (VB_1+VthPT4)˜V2 in the AC operation. The output voltage OUT may be fixed to (VB_1+VthPT4) or V2 in the DC operation. Thus, the reliability of the switching elements PT1, PT2, PT3, PT4, PT5 and PT6 configured to receive the second power voltage V2 may be secured.

The voltage Vtp shown in FIG. 13B may be a threshold voltage Vth_PT4 of the switching element PT4. That is, the first PMOS gate signal PG<1>shown in FIG. 13B has the variation range corresponding to VB_1+Vth_PT4 to V2.

The sixth switching element PT6 may include one end connected to the terminal of the second power voltage V2, another end connected to the terminal of the output voltage OUT, and a control end receiving the compensation voltage V_TIE.

The seventh to ninth switching elements PT5, NT6, and NT7 may be connected between the terminal of the second power voltage V2 and the ground terminal, and may generate the compensation voltage V_TIE according to the second power voltage V2.

Current mirroring of the sixth switching element PT6 may be performed according to the compensation voltage V_TIE generated by the seventh to ninth switching elements PT5, NT6, and NT7, and a current according thereto may be supplied to the terminal of the output voltage OUT.

Since the sixth switching element PT6 continuously supplies the current to the terminal of the output voltage OUT, the output voltage OUT may be prevented from being lower than VB_1+Vth_PT4 even though the input signal IN of a high level is input to the control end of the first switching element NT1.

In example embodiments, the compensation voltage V_TIE may be set below such that a voltage difference between compensation voltage V_TIE and the second power voltage V2 may be below maximum operating voltage. Further, the compensation voltage V_TIE may be turned-off the sixth switching element PT6 corresponding the output voltage compensator 411. Although the sixth switching element PT6 may be turned-off by the compensation voltage V_TIE, an off-current of the sixth switching element PT6 may be continuously provided to the output voltage terminal.

The second power voltage V2 may be applied to the source of the seventh switching element PT5 in the compensation voltage generator 1412. The gate and the drain of the seventh switching element PT5 may be commonly connected with each other. The compensation voltage V_TIE may be generated from the gate and the drain of the seventh switching element PT5. The drain of the eighth switching element NT6 may be connected to the drain of the seventh switching element PT5. The gate of the eighth switching element PT6 may receive the second power voltage V2. The drain of the ninth switching element NT7 may be connected to the drain of the eighth switching element NT6. The gate and the source of the ninth switching element NT7 may be connected in common.

When the level shifter 1400 is driven for a long time, heat dissipation may be generated. When a driving force of the NMOS transistors NT1˜NT4 constituting the current mirror 1420 may be increased due to the heat dissipation, the output voltage of the level shifter 1400 may be decreased. The compensation voltage generator 1412 of example embodiments may include the eighth and ninth switching elements NT6 and NT7 reflecting on the driving force of the NMOS transistors NT1˜NT4 of the current mirror 1420. Thus, current amount discharged by the NMOS transistors NT1˜NT4 of the current mirror 1420 may be compensated by the eighth and the ninth switching elements NT6 and NT7.

Further, the current of the output voltage compensator 1411 may mirror the current of the compensation voltage generator 1412, the compensated off-current may also be provided to the output voltage compensator 1411 to continuously maintain the output voltage OUT of no less than VB_1+Vth_PT4.

The sixth switching element PT6 prevents the output voltage OUT from being lower than VB_1+Vth_PT4, and thus operation reliability of the third switching element PT1 may be guaranteed.

In embodiments, the output voltage OUT of the sixth switching element PT6 may be maintained above VB_1+Vth_PT4 to secure the reliability of the third switching element PT1 directly receiving the second power voltage V2. Further, because the output voltage OUT may be within VB_1+Vth_PT4˜V2, the reliability of the switching elements PT1, PT2 and PT3 controlled by the output voltage OUT may be secured.

The tenth switching element NT3 includes one end connected to the node NODE_3, another end connected to the node NODE_4, and a control end receiving the first power voltage V1.

Since the tenth switching element NT3 receives the first power voltage V1 through the control end, operation reliability of the first switching element NT1 may be secured by lowering a voltage of the node NODE_4 by V1-Vth_NT3, Vth_NT3 denoting a threshold voltage of the tenth switching element NT3.

The eleventh switching element NT4 includes one end connected to the node NODE_5, another end connected to a node NODE_6, and a control end receiving the first power voltage V1.

The eleventh switching element NT4 may also operate in the same manner as the tenth switching element NT3 to secure an operation reliability of the twelfth switching element NT5, which is described later.

The delay circuit 1453 may be implemented as an inverter array 1453 including a plurality of inverters 1522.

The inverter array 1453 may delay and invert the inverted input signal INB to generate a delayed input signal IN_Delay.

The twelfth switching element NT5 includes one end connected to the node NODE_6, another end connected to the node NODE_7, and a control end receiving the delayed input signal IN_Delay.

The twelfth switching element NT5 may operate at a time difference from the second switching element NT2 according to the delayed input signal IN_Delay to minimize the leakage current by preventing a current path from being formed for more than a time required for a level transition of the terminal of the output voltage OUT.

For example, the twelfth switching element NT5 may be turned on a given time interval after the second switching element NT2 has been turned on, the given time interval corresponding to the delay amount of the delay circuit 1453.

FIG. 14 shows the configuration of the level shifter 1400 generating the output signal OUT corresponding to the first PMOS gate signal PG<1> in FIG. 13B. However, embodiments of the present disclosure are not limited thereto. A level shifter according to an embodiment of the present disclosure may also generate the second to n-th PMOS gate signals PG<2: n>identically to the first PMOS gate signal PG<1>.

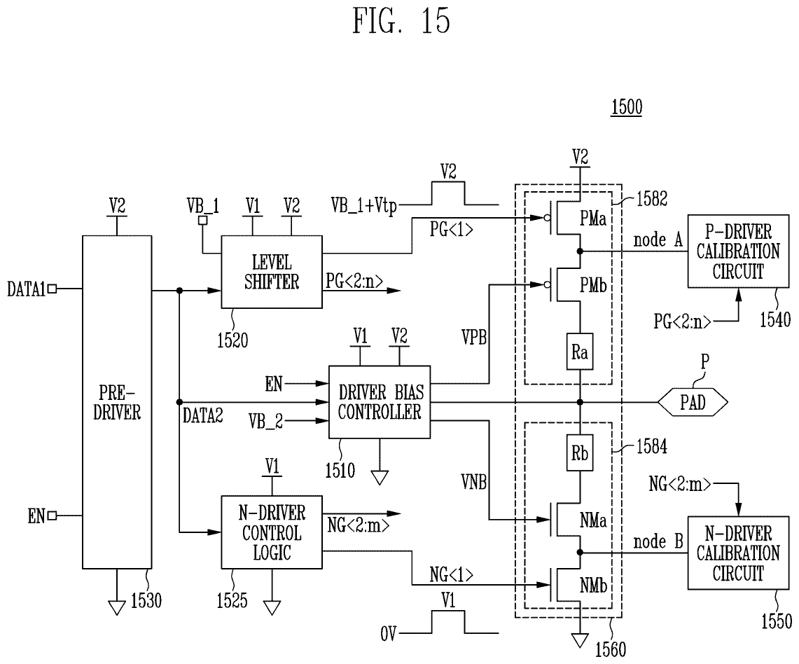

FIG. 15 is a block diagram illustrating an interface circuit block 1500 according to still an embodiment of the present disclosure.

Referring to FIG. 15, the interface circuit block 1500 includes a pre-driver 1530, a level shifter 1520, a driver control logic (e.g., an N-driver control logic) 1525, a first driver calibration circuit (e.g., a P-driver calibration circuit) 1540, a second driver calibration circuit (e.g., an N-driver calibration circuit) 1550, an output driver 1560, and a driver bias controller 1510. The pull-up-down driver 1560 includes a first PMOS transistor PMa, a second PMOS transistor PMb, a first NMOS transistor Nma, a second NMOS transistor NMb, a first resistor Ra, and a second resistor Rb. For example, the output driver 1560 includes a pull-up driver 1582 and a pull-down driver 1584, such that the pull-up driver 1582 includes the first PMOS transistor PMa, the second PMOS transistor PMb, and the first resistor Ra, and the pull-down driver 1584 includes the first NMOS transistor Nma, the second NMOS transistor NMb, and the second resistor Rb. In FIG. 15, the pre-driver 1530, the level shifter 1520, the N-driver control logic 1525, the P-driver calibration circuit 1540, and the N-driver calibration circuit 1550 may be substantially the same as the pre-driver 1330, the level shifter 1320, the N-driver control logic 1325, the P-driver calibration circuit 1340, and the N-driver calibration circuit 1350 shown in FIG. 13B, respectively. Therefore, repetitive description of the pre-driver 1530, the level shifter 1520, the N-driver control logic 1525, the P-driver calibration circuit 1540, and the N-driver calibration circuit 1550 is omitted.

The driver bias controller 1510 may operate based on the first and second power voltages V1 and V2. In addition, the driver bias controller 1510 may be connected to the pad and receive the enable signal EN, the second data signal DATA2, and the second bias voltage VB_2. The driver bias controller 1510 generates a first bias voltage (e.g., a P-bias voltage) VPB and a second bias voltage (e.g., an N-bias voltage) VNB that change according to a pad state, based on one or more of the received signals. The P-bias voltage VPB is applied to the second PMOS transistor PMb of the output driver 1560. The N-bias voltage VNB is applied to the first NMOS transistor NMa of the output driver 1560. The driver bias controller 1510 controls the P-bias voltage VPB to have a value between the second bias voltage VB_2 and the first power voltage V1, according to the state of the pad. As the P-bias voltage VPB has the value between the second bias voltage VB_2 and the first power voltage V1, when a voltage of the pad has a voltage value between 0V and the second power voltage V2, the reliability condition of the low voltage transistor is satisfied during an operation of the second PMOS transistor PMb.

In addition, the driver bias controller 1510 controls the N-bias voltage VNB to have a value between the first power voltage V1 and the second power voltage V2, according to the state of the pad. As the N-bias voltage VNB has the value between the first power voltage V1 and the second power voltage V2, when the voltage of the pad has a voltage value between 0V and the second power voltage V2, the reliability condition of the low voltage transistor with a thin gate oxide is satisfied during an operation of the first NMOS transistor NMa.

A preferred interface circuit block is disclosed in U.S. patent application Ser. No. 17/076,474, filed Oct. 21, 2020 and entitled, “OUTPUT DRIVING CIRCUIT,” the entire disclosure of which is incorporated herein by reference.

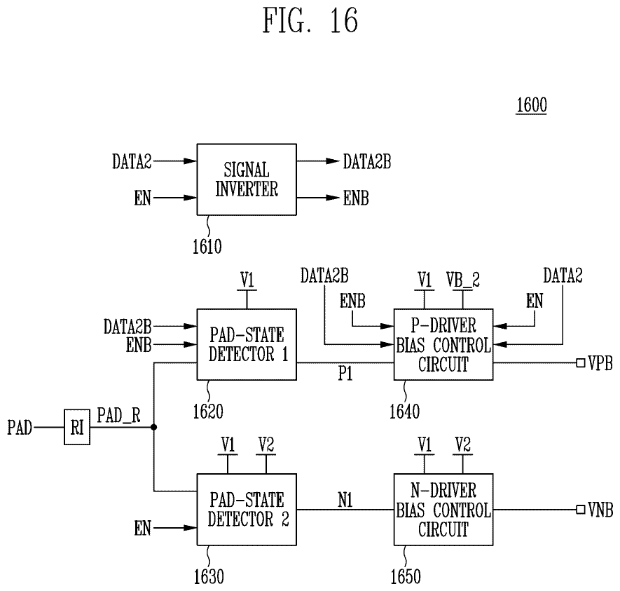

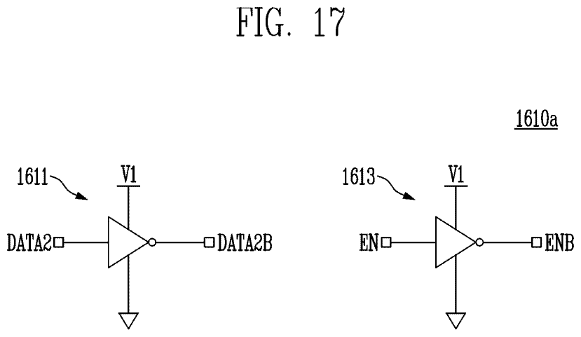

An embodiment of the driver bias controller 1510 shown in FIG. 15 is described with reference to FIG. 16.

FIG. 16 is a block diagram illustrating a driver bias controller 1600 according to an embodiment of the present disclosure.

Referring to FIG. 7, the driver bias controller 1600 includes a signal inverter 1610, a first pad-state detector 1620, a second pad-state detector 1630, a P-driver bias control circuit 1640, an N-driver bias control circuit 1650, and an internal resistor RI. The internal resistor R1 is connected to the pad. The P-driver bias control circuit 1640 and the N-driver bias control circuit 1650 are connected to the internal resistor RI. The internal resistor R1 may be used for the ESD protection resistor, the impedance control resistor or the voltage stabilization resistor.

The signal inverter 1610 may receive the second data signal DATA2 and the enable signal EN to generate a second inverted data signal DATA2B and an inverted enable signal ENB. An example configuration of the signal inverter 1610 is described later with reference to FIG. 17.

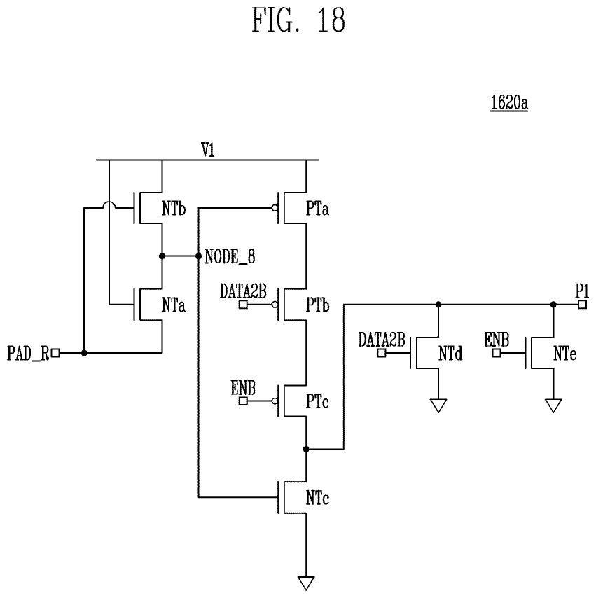

The first pad-state detector 1620 detects a voltage state of the pad having a voltage between 0V and the second power voltage V2 through the internal resistor RI. More specifically, the voltage of the pad may be changed from a low voltage to a high voltage or from a high voltage to a low voltage, in a range of 0V to the second power voltage V2. The first pad-state detector 1620 detects the voltage state of the pad, which is changed as described above, and outputs a detection result to a node P1. To this end, the first pad-state detector 1620 operates based on the first power voltage V1 and receives the second inverted data signal DATA2B and the inverted enable signal ENB. A specific configuration of the first pad-state detector 1620 is described with reference to FIG. 18.

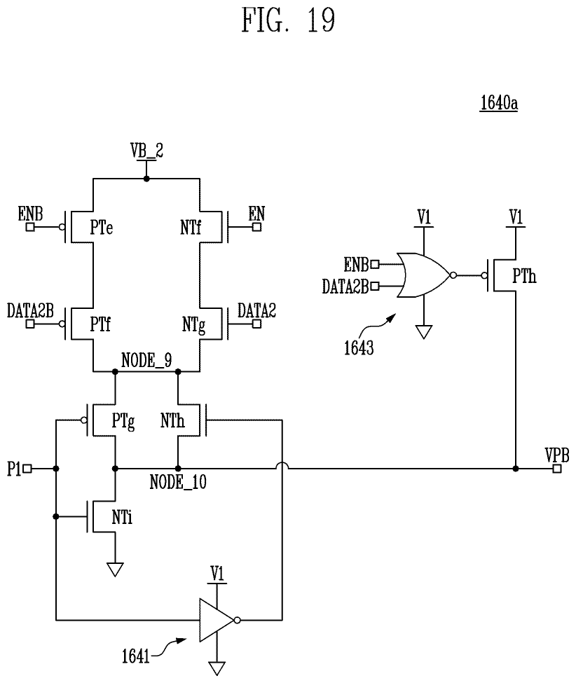

The P-driver bias control circuit 1640 is connected to the first pad-state detector 1620 through the node P1. The P-driver bias control circuit 1640 may operate based on the first power voltage V1 and the second bias voltage VB_2. In addition, the P-driver bias control circuit 1640 receives the second data signal DATA2, the enable signal EN, the second inverted data signal DATA2B, and the inverted enable signal ENB. The P-driver bias control circuit 1640 generates a P-bias voltage VPB according to the second inverted data signal DATA2B input based on the pad state detected by the first pad-state detector 1620. A specific configuration of the P-driver bias control circuit 1640 is described with reference to FIG. 19.

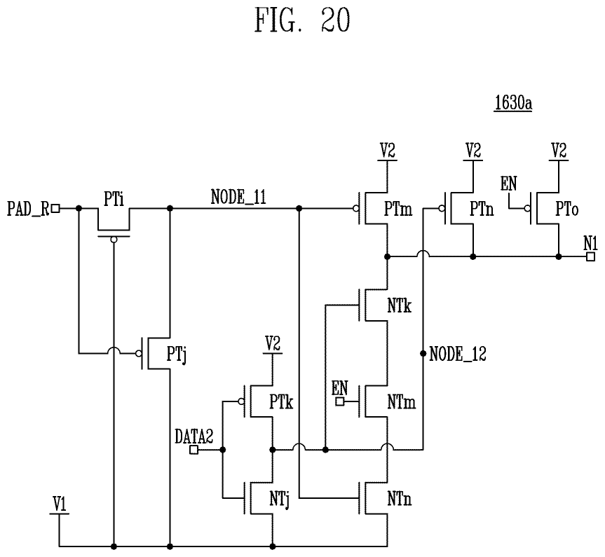

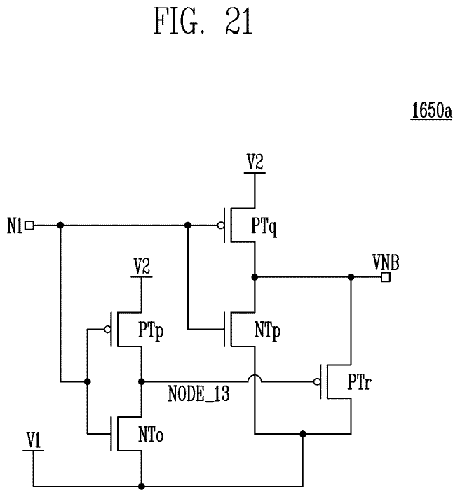

The second pad-state detector 1630 detects the voltage state of the pad having the voltage between 0V and the second power voltage V2 through the internal resistor RI. More specifically, the voltage of the pad may be changed from a low voltage to a high voltage or from a high voltage to a low voltage in a range of 0V to the second power voltage V2. The second pad-state detector 1630 detects the voltage state of the pad, which is changed as described above, and outputs the detection result to a node N1. To this end, the second pad-state detector 1630 operates based on the first and second power voltages V1 and V2, and receives the enable signal EN. In addition, although not shown in FIG. 16, the second pad-state detector 1630 may receive the first PMOS gate signal PG<1>generated by the level shifter 1520. A specific configuration of the second pad-state detector 1630 is described with reference to FIG. 20.

The N-driver bias control circuit 1650 is connected to the second pad-state detector 1630 through the node N1. The N-driver bias control circuit 1650 generates an N-bias voltage VNB according to the pad state detected by the second pad-state detector 1630. The N-driver bias control circuit 1650 may operate based on the first and second power voltages V1 and V2. A specific configuration of the N-driver bias control circuit 1650 is described with reference to FIG. 21.

FIG. 17 is a diagram illustrating a signal inverter 1610a suitable for use as the signal inverter 1610 of FIG. 16, according to an embodiment. Referring to FIG. 17, the signal inverter 1610a may include a plurality of inverters 1611 and 1613. The inverter 1611 operates based on the first power voltage V1, and inverts the second data signal DATA2 to output the second inverted data signal DATA2B. The inverter 1613 operates based on the first power voltage V1, and inverts the enable signal EN to output the inverted enable signal ENB. Since the plurality of inverters 1611 and 1613 operate based on the first power voltage V1, each of the second inverted data signal DATA2B and the inverted enable signal ENB may be signals having a voltage value between 0V and the first power voltage V1.

FIG. 18 is a diagram illustrating a first pad-state detector 1620a suitable for use as the first pad-state detector 1620 of FIG. 16, according to an embodiment.

Referring to FIG. 18, the first pad-state detector 1620 includes NMOS transistors NTa, NTb, NTc, NTd, and NTe and PMOS transistors PTa, PTb, and PTc. The NMOS transistors NTa and NTb are connected in series between the first power voltage V1 and a node PAD_R. The first pad-state detector 1620 is connected to the resistor RI of FIG. 16 through the node PAD_R. In an embodiment, a voltage of the node PAD_R may be the same as the voltage of the pad. A gate of the NMOS transistor NTa is connected to the first power voltage V1, and a gate of the NMOS transistor NTb is connected to the node PAD_R. The NMOS transistor NTb is included to block a leakage current. When there is no NMOS transistor NTb, a voltage of a node Node_8 has a level value of the first power voltage V1-a threshold voltage VTNTa1 of the NMOS transistor NTa. In this case, since a voltage of V1-VTNTa is supplied to a gate of the PMOS transistor PTa or a gate of the NMOS transistor NTc, not the first power voltage V1, a leakage current path may be generated. When the NMOS transistor NTb is connected between the first power voltage V1 and the node NODE_8, the first power voltage V1 is completely supplied to the node NODE_8 to prevent an occurrence of the leakage current. In other words, since the NMOS transistor NTb is connected between the first power voltage V1 and the node NODE_8 as shown in FIG. 18, the voltage of the node NODE_8 may have a level substantially equal to the first power voltage

V1, rather than V1-VTNM1, thereby preventing an occurrence of the leakage current.

The PMOS transistors PTa, PTb, and PTc are connected in series between the first power voltage V1 and the node P1. The gate of the PMOS transistor PTa is connected to the node NODE_8. The second inverted data signal DATA2B is applied to the gate of the PMOS transistor PTb. The inverted enable signal ENB is applied to a gate of the PMOS transistor PTc.

When the enable signal EN is deactivated to a logic low, the inverted enable signal ENB is activated to a logic high. Therefore, in this case, the PMOS transistor PTc is turned off, and thus a voltage transfer path between the first power voltage V1 and the node P1 is blocked regardless of the second data signal DATA2.

The NMOS transistor NTc is connected between the node P1 and the ground. The gate of the NMOS transistor NTc is connected to the node NODE_8.

The NMOS transistors NTd and NTe are connected in parallel between the node P1 and the ground. The second inverted data signal DATA2B is applied to a gate of the NMOS transistor NTd. The inverted enable signal ENB is applied to a gate of the NMOS transistor NTe.

When the enable signal EN is deactivated to a logic low, the inverted enable signal ENB is activated to a logic high. Therefore, in this case, the NMOS transistor NTe is turned on, and thus the voltage of the node P1 maintains a low level regardless of the second data signal DATA2.

According to a circuit structure of FIG. 18, the voltage of the node P1 is determined according to the pad voltage and the second data signal DATA2. When the voltage of the pad P is a low voltage, for example, the ground voltage and a signal of the second inverted data signal DATA2B is a voltage of a logic high state, the PMOS transistor

PTb is turned off and the NMOS transistor NTd is turned on, and thus the voltage of the node P1 becomes a logic low state.

The voltage state of the pad is the same as that of the second data signal DATA2, but some delay may occur between the two states. That is, when the second data signal DATA2 is changed from a logic low state to a logic high state, that is, when the second inverted data signal DATA2B is changed from a logic high state to a logic low state, the pad voltage maintains a logic low state during a certain time period from a time point of the change. In this period, this causes the voltage of the node P1 to be in a logic low state by the NMOS transistor NTd. The PMOS transistor PTb receiving the second inverted data signal DATA2B having a logic low state through the gate is turned on and the NMOS transistor NTd is turned off. Therefore, the voltage of the node P1 temporarily increases to the first power voltage V1. That is, the second inverted data signal DATA2B has a logic low state, the inverted enable signal ENB has a logic low state, and the pad voltage has a logic low state during a given time period, the PMOS transistors PTa, PTb, PTc are turned on and the NMOS transistors NTc, NTd, and NTe are turned off. As a result, the first power voltage V1 and the node P1 are coupled to increase the voltage of the node P1 substantially equal to the first power voltage V1. Subsequently, the pad voltage changes to a logic high state to turn on the NMOS transistor NTb, and thus the voltage of the node NODE_8 increases to turn on the NMOS transistor NTc, thereby coupling the node P1 to the ground. Accordingly, the voltage of the node P1 increases to the first power voltage V1 during the time period, and then decreases.

FIG. 19 is a diagram illustrating a P-driver bias control circuit 1640a suitable for use as the P-driver bias control circuit 1640 of FIG. 16, according to an embodiment. Referring to FIG. 19, the P-driver bias control circuit 1640a may include NMOS transistors NTf, NTg, NTh, and NTi, PMOS transistors PTe, PTf, PTg, and PTh, an inverter 1641, and a negative-OR gate (NOR gate) 1643. The NMOS transistors NTf and NTg are connected in series between the second bias voltage VB_2 and a node NODE_9. The enable signal EN is applied to a gate of the NMOS transistor NTf, and the second data signal DATA2 is applied to a gate of the NMOS transistor NTg. The PMOS transistors PTe and PTf are connected in series between the second bias voltage VB_2 and the node NODE_9. The inverted enable signal ENB and the second inverted data signal DATA2B are applied to gate terminals of the PMOS transistors PTe and PTf, respectively.

The PMOS transistor PTg and the NMOS transistor NTh are connected in parallel between the node NODE_9 and a node NODE_10. The node NODE_10 may be directly connected to an output terminal of the P-driver bias control circuit 1640. The P-bias voltage VPB is output through the output terminal of the P-driver bias control circuit 1640. Meanwhile, the NMOS transistor NTi is connected between the node NODE_10 and the ground.

A gate terminal of the PMOS transistor PTg and a gate terminal of the NMOS transistor NTi are connected to the node P1. The node P1 may be an output node of the first pad-state detector 1620. Meanwhile, an input terminal of the inverter 1641 may be connected to the node P1, and an output terminal of the inverter 1641 may be connected to the gate of the NMOS transistor NTh.

The NOR gate 1643 performs an NOR operation on the inverted enable signal ENB and the second inverted data signal DATA2B, and output the operation result to the gate of the PMOS transistor PTh. The PMOS transistor PTh is connected between the first power voltage V1 and an output terminal VPB of the P-driver bias control circuit 1640a. In a case of the NOR gate 1643, an output of a logic-low is applied to the gate of the PMOS transistor PTh regardless of a level of the second inverted data signal DATA2B while the inverted enable signal ENB has a logic-high state. In this case, the PMOS transistor PTh is turned on to output the first power voltage V1 to the output terminal. At this time, the second PMOS transistor PMb shown in FIG. 15 is turned off.

When a voltage level of the node P1 is a low level, a voltage VPB of the output terminal becomes the first power voltage V1. In this state, when a voltage level of the second data signal DATA2 increases from a low level to a high level, the voltage of the node P1 temporarily increases to a level of the first power voltage V1. As the voltage level of the node P1 increases, the NMOS transistor NTi is turned on, and thus the P-bias voltage VPB output to the output terminal temporarily decreases to a low level, that is, the ground voltage level.

When the voltage VPB of the output terminal is the first power voltage V1, this voltage is applied to the gate of the second PMOS transistor PMb of FIG. 15. At this time, a source voltage of the second PMOS transistor PMb, that is, a voltage of the node NODE_A has a level of the first power voltage V1+a threshold voltage VTPMb of the second PMOS transistor PMb. Since a drain voltage of the second PMOS transistor PMb, that is, the voltage of the pad P is a low level, in a state in which the voltage of the pad P is not increased to the first power voltage V1 or more, even though the P-bias voltage VPB momentarily decreases to a low level, for example, 0V, the gate-source voltage VGS, the gate-drain voltage VGD, and the drain-source voltage VDS of the second PMOS transistor PMb are within the reliability range condition.

In a situation in which the voltage of the pad P increases to the first power voltage V1 or more, the voltage of the node P1 decreases again to a low level. At this time, the P-bias voltage VPB temporarily increases to the first power voltage V1 to satisfy the reliability condition of the second PMOS transistor PMb. Thereafter, the P-bias voltage VPB is changed to the second bias voltage VB_2 in a state in which the voltage of the pad P is stabilized to the second power voltage V2.

Accordingly, the first pad-state detector 1620 and the P-driver bias control circuit 1640 output the P-bias voltage VPB having a voltage value between the second bias voltage VB_2 and the first power voltage V1. Accordingly, the second PMOS transistor PMb may operate in a state that satisfies the reliability condition.

As a result, the second PMOS transistor PMb may be driven based on the voltage level of the pad P. Thus, the second PMOS transistor PMb may be driven in consideration on a duty ratio between a voltage-variation of the node A and a delay time at which the second data signal DATA 2 is transmitted to the pad P.

FIG. 20 is a diagram illustrating a second pad-state detector 1630a suitable for use as the second pad-state detector 1630 of FIG. 16, according to an embodiment.

Referring to FIG. 20, the second pad-state detector 1630a may include NMOS transistors NTj, NTk, NTm, and NTn, and PMOS transistors PTi, PTj, PTk, PTm, PTn, and PTo.

The PMOS transistor PTi is connected between the node PAD_R and a node NODE_11. A gate of the PMOS transistor PTi is connected to the first power voltage V1. The PMOS transistor PTj is connected between the node NODE_11 and the first power voltage V1. A gate of the PMOS transistor PTj is connected to the node PAD_R. The PMOS transistor PTk and the NMOS transistor NTj are connected in series between the second power voltage V2 and the first power voltage V1. Gates of the PMOS transistor PTk and the NMOS transistor NTj are connected to the first PMOS gate signal PG<1>. The PMOS transistor PTm is connected between the second power voltage V2 and the node N1. A gate of the PMOS transistor PTm is connected to the node NODE_11. The NMOS transistors NTk, NTm, and NTn are connected in series between the node N1 and the first power voltage V1. A gate of the NMOS transistor NTk is connected to a node NODE_12. The enable signal EN is applied to a gate of the NMOS transistor NTm. The node NODE_11 is connected to a gate of the NMOS transistor NTn.

The PMOS transistors PTn and PTo are connected in parallel between the second power voltage V2 and the node N1. A gate of the PMOS transistor PTn is connected to a node NODE_12. A gate of the PMOS transistor PTo is connected to the enable signal EN.

When the second data signal DATA2 has a low level voltage value, and thus, the voltage of the pad P is 0V, the PMOS transistor PTk may be turned on by the second data signal DATA2 of a low state. Accordingly, a voltage of the node NODE_12 becomes a level of the second power voltage V2. When the voltage of the pad P increases to a high level, for example, the level of the second power voltage V2, the NMOS transistor NTj may be turned on by the second data signal DATA2 of a high state. Accordingly, the voltage of the node NODE_12 becomes a level of the first power voltage V1.

When the voltage of the pad P is changed from a high level to a low level, due to a delay time between the voltage of the pad P and the second data signal DATA2, a voltage level of the node NODE_12 temporarily decreases from the second power voltage V2 to the first power voltage V1.

In addition, when the enable signal EN is activated to a high level, an inverter configured of the PMOS transistor PTm and the NMOS transistor NTk, NTm, and NTn is activated. In this case, the voltage of the node NODE_12 is changed according to the voltage of the pad P and the node PAD_R. When the enable signal EN is deactivated to a low level, the inverter configured of the PMOS transistor PTm and the NMOS transistors NTk, NTm, and NTn is deactivated, and the voltage of the node N1 is fixed to the second power voltage V2 by the PMOS transistor PTo.

FIG. 21 is a diagram illustrating an N-driver bias control circuit 1650a suitable for used as the N-driver bias control circuit 1650 of FIG. 16, according to an embodiment. Referring to FIG. 21, the N-driver bias control circuit 1650a includes NMOS transistors NTo and NTp and PMOS transistors PTp, PTq, and PTr.

The PMOS transistor PTp and the NMOS transistor NTo are connected between the second power voltage V2 and the first power voltage V1. Gates of the PMOS transistor PTp and the NMOS transistor NTo are connected to the node N1. The PMOS transistor PTp and the NMOS transistor NTo are connected to each other through a node NODE_13.

Meanwhile, the PMOS transistor PTq and the NMOS transistor NTp are connected between the second power voltage V2 and the first power voltage V1. Gates of the PMOS transistor PTq and the NMOS transistor NTp are connected to the node N1. The PMOS transistor PTq and the NMOS transistor NTp are connected to each other by a node outputting the N-bias voltage VNB.

The PMOS transistor PTr is connected between the node outputting the N-bias voltage VNB and the first power voltage V1. A gate of the PMOS transistor PTr is connected to the node NODE_13.

When a voltage level of the node N1 as the input terminal is the second power voltage V2, the N-bias voltage VNB becomes the level of the first power voltage V1 by the NMOS transistor NTp. When the voltage of the node N1 temporarily decreases from the second power voltage V2 to the first power voltage V1 due to a delay between the voltage of the pad P and the second data signal DATA2, the N-bias voltage VNB is temporarily increased to the second power voltage V2.

Accordingly, the second pad-state detector 1630 and the N-driver bias control circuit 1650a output the N-bias voltage VNB having a voltage value between the first power voltage V1 and the second power voltage V2. Thus, the first NMOS transistor NMa may operate in a state that satisfies the reliability condition.

As a result, the first NMOS transistor NMa may be driven based on the voltage level of the pad P. Thus, the first NMOS transistor NMa may be driven in consideration on a duty ratio between a voltage-variation of the node B and the delay time at which the second data signal DATA 2 is transmitted to the pad P.

While various embodiments have been described above, it will be understood to those skilled in the art that the embodiments described are examples only. Accordingly, the electrostatic discharge circuit and the electrostatic discharge control system, which have been described herein, should not be limited based on the described embodiments.

What is claimed is:

1. An electrostatic discharge control system, comprising:
a first electrostatic discharge circuit configured to perform a discharge operation on static electricity contained in a first supply voltage; and
a second electrostatic discharge circuit configured to perform a discharge operation on static electricity contained in a second supply voltage.

2. The electrostatic discharge control system of claim 1,
wherein the first supply voltage has a higher voltage level than the second supply voltage.

3. The electrostatic discharge control system of claim 1, further comprising:
a selection control circuit configured to selectively control the first or second electrostatic discharge circuit based on a selected supply voltage of the first and second supply voltages.

4. The electrostatic discharge control system of claim 3, wherein the selected supply voltage is applied to a supply voltage terminal.

5. The electrostatic discharge control system of claim 1, wherein the first electrostatic discharge circuit comprises:
a control voltage generation circuit configured to generate a first control voltage, a second control voltage, and a third control voltage by dividing a first supply voltage.

6. The electrostatic discharge control system of claim 1, wherein the first electrostatic discharge circuit comprises:
an electrostatic detection circuit configured to set a first setup voltage based on the first control voltage, and generate an electrostatic detection signal by detecting static electricity contained in the first setup voltage.

7. The electrostatic discharge control system of claim 1, wherein the first electrostatic discharge circuit comprises:
a driving control circuit configured to set a second setup voltage based on the second control voltage, and generate a driving control signal based on the electrostatic detection signal.

8. The electrostatic discharge control system of claim 1, wherein the first electrostatic discharge circuit comprises:
a discharge driving circuit configured to set a third setup voltage based on the third control voltage, and perform a discharge operation on static electricity contained in the third setup voltage based on the driving control signal.

9. The electrostatic discharge control system according to claim 1, wherein the selection control circuit selectively provides the first or second supply voltage to the first or second electrostatic discharge circuit, respectively.

10. The electrostatic discharge control system according to claim 3, wherein the selection control circuit comprises:
a first comparison circuit configured to compare the selected supply voltage to a first reference voltage corresponding to the first supply voltage; and
a second comparison circuit configured to compare the selected supply voltage to a second reference voltage corresponding to the second supply voltage.

11. The electrostatic discharge control system according to claim 3, wherein the selection control circuit comprises:
a control circuit configured to generate a selection control signal based on output signals of a first and second comparison circuits; and
an output circuit configured to selectively output the first or second supply voltage in response to the selection control signal.

12. The electrostatic discharge control system according to claim 1, wherein the electrostatic detection circuit comprises a first low voltage transistor configured to receive the first control voltage, and
wherein the driving control circuit comprises a second low voltage transistor configured to receive the second control voltage, and a third low voltage transistor configured to receive the electrostatic detection signal.

13. The electrostatic discharge control system according to claim 1, wherein the electrostatic detection circuit comprises a first low voltage transistor configured to receive the first control voltage, and
wherein the discharge driving circuit comprises a fourth low voltage transistor configured to receive the third control voltage, and a fifth low voltage transistor configured to receive the driving control signal.

14. The electrostatic discharge control system according to claim 1, wherein the second electrostatic discharge circuit comprises:
a detection circuit configured to detect static electricity contained in the second supply voltage.

15. The electrostatic discharge control system according to claim 1, wherein the second electrostatic discharge circuit comprises:
a driving circuit configured to generate a control signal based on an output signal of the detection circuit.

16. The electrostatic discharge control system according to claim 1, wherein the second electrostatic discharge circuit comprises:
a discharge circuit configured to form a discharge path for the second supply voltage based on the control signal.

17. The electrostatic discharge control system according to claim 1, wherein the control voltage generation circuit comprises:
a transfer circuit configured to transfer the first supply voltage in response to a selection control signal.

18. The electrostatic discharge control system according to claim 1, wherein the control voltage generation circuit comprises:
a voltage dividing circuit configured to receive a voltage transferred through the transfer circuit, and generate the first to third control voltages by dividing the receive voltage.

19. An electrostatic discharge control system, comprising:
a control signal generation circuit configured to generate a selection control signal based on a selected supply voltage of a first supply voltage and a second supply voltage, the selected supply voltage being applied to a supply voltage terminal;
a control voltage generation circuit activated in response to the selection control signal when the selected supply voltage is the first supply voltage and configured to generate a first control voltage, a second control voltage, and a third control voltage by dividing the selected supply voltage;
a first setup circuit configured to receive the selected supply voltage and generate a first setup voltage based on one of the first control voltage and the selection control signal;
a detection circuit configured to detect static electricity contained in the first setup voltage and output an electrostatic detection signal;
a second setup circuit configured to receive the selected supply voltage and generate a second setup voltage based on one of the second control voltage and the selection control signal;
a driving circuit configured to generate a driving control signal based on the electrostatic detection signal;
a third setup circuit configured to receive the selected supply voltage and generate a third setup voltage based on one of the third control voltage and the selection control signal; and
a discharge circuit configured to form a discharge path for the third setup voltage based on the driving control signal.

20. The electrostatic discharge control system according to claim 19, wherein the control signal generation circuit comprises:
a first comparison circuit configured to compare the selected supply voltage to a first reference voltage corresponding to the first supply voltage;
a second comparison circuit configured to compare the selected supply voltage to a second reference voltage corresponding to the second supply voltage; and
a control circuit configured to generate the selection control signal based on output signals of the first and second comparison circuits.

21. The electrostatic discharge control system according to claim 19, wherein the first setup circuit comprises a first low voltage NMOS transistor configured to receive the first control voltage,
the second setup circuit comprises a second low voltage NMOS transistor configured to receive the second control voltage, and
the third setup circuit comprises a third low voltage NMOS transistor configured to receive the third control voltage.

22. The electrostatic discharge control system according to claim 19, wherein the first setup circuit further comprises a first low voltage PMOS transistor and coupled in parallel to the first low voltage NMOS transistor and configured to receive the selection control signal, and
herein the second setup circuit further comprises a second low voltage PMOS transistor and coupled in parallel to the second low voltage NMOS transistor and configured to receive the selection control signal, and
the third setup circuit comprises a third low voltage PMOS transistor and coupled in parallel to the third low voltage NMOS transistor and configured to receive the selection control signal.

23. An electronic system, comprising:
a first electrostatic discharge circuit configured to perform a discharge operation on static electricity included in a first supply voltage;
a second electrostatic discharge circuit configured to perform a discharge operation on static electricity contained in a second supply voltage being lower than, the first supply voltage; and
a selection control circuit configured to selectively control one of the first and second electrostatic discharge circuits based on a selected supply voltage of the first and second supply voltages, the selected supply voltage being applied to a supply voltage terminal,
wherein the first electrostatic discharge circuit includes at least one low voltage transistor which has a driving voltage lower than the first supply voltage.
